(19) United States
(12) Patent Application Publication
(10) Pub. No.: US 2018/0039170 A1
(43) Pub. Date: Feb. 8, 2018

(54) NANONIMPRINT LIQUID MATERIAL, METHOD FOR MANUFACTURING NANOIMPRINT LIQUID MATERIAL, METHOD FOR MANUFACTURING CURED PRODUCT PATTERN, METHOD FOR MANUFACTURING OPTICAL COMPONENT, AND METHOD FOR MANUFACTURING CIRCUIT BOARD

(71) Applicant: CANON KABUSHIKI KAISHA, Tokyo (JP)

(72) Inventors: Jun Kato, Yokohama-shi (JP); Takeshi Honma, Tokyo (JP); Toshiki Ito, Kawasaki-shi (JP)

(21) Appl. No.: 15/553,938

(22) PCT Filed: Feb. 23, 2016
(86) PCT No.: PCT/JP2016/000956

§ 371 Date: Aug. 25, 2017

(30) Foreign Application Priority Data
Feb. 27, 2015 (JP) 2015-039399
Feb. 19, 2016 (JP) 2016-030332

(51) Int. Cl. G03F 7/00; B29C 59/02; B29D 11/00; H01L 21/48; G03F 7/029; H01L 21/3105; H01L 21/266; C08L 35/02; G02B 1/04; B29C 59/00; H05K 3/00

(52) U.S. Cl. CPC G03F 7/0002; B29C 59/005; B29C 59/02; B29D 11/00269; B29D 11/00769; H01L 21/481; H05K 3/0017; H01L 21/3105; H01L 21/266; C08L 35/02; G02B 1/04; G03F 7/029; B29K 2033/08

(57) ABSTRACT

A nanoimprint liquid material in which the particle number concentration of particles having a particle diameter of 0.07 μm or more is less than 310/mL is provided.

### TECHNICAL FIELD

The present invention relates to a nanoimprint liquid material, a method for manufacturing a nanoimprint liquid material, a method for manufacturing a cured product pattern, a method for manufacturing an optical component, and a method for manufacturing a circuit board.

### BACKGROUND ART

In semiconductor devices, MEMS, and the like, miniaturization has been increasing required, and in particular, a photo-nanoimprint technique has drawn attention.

In the photo-nanoimprint technique, in the state in which a mold having a fine concave-convex pattern formed in its surface is pressed to a substrate (wafer) on which a photocurable composition (resist) is applied, the resist is cured. By this technique, the concave-convex pattern of the mold is transferred to a cured product of the resist, so that the pattern is formed on the substrate. According to the photo-nanoimprint technique, a fine structural body on the order of several nanometers can be formed on the substrate.

In the photo-nanoimprint technique, first, a resist is applied to a pattern forming region on a substrate (arrangement step). Next, this resist is molded using a mold in which a pattern is formed (mold contact step). Subsequently, after the resist is cured (light irradiation step) by light irradiation, the resist thus cured is released from the mold (mold release step). Through the steps described above, a resin pattern (photo cured product) having a predetermined shape is formed on the substrate. Furthermore, all the steps described above are repeatedly performed on different positions on the substrate, so that a fine structural body can be formed over the entire substrate.

### CITATION LIST

### Patent Literature

PTL 1: Japanese Patent Laid-Open No. 2010-073811

### SUMMARY OF INVENTION

### Technical Problem

In a nanoimprint technique including a photo-nanoimprint technique, pattern transfer and molding are performed by bringing a mold into contact with a resist applied on a substrate. Hence, when a foreign substance having a predetermined size or more is present in a resist to be applied on the substrate in an arrangement step, a concave-convex pattern of the mold may be damaged or blocked thereby in some cases.

In particular, in the case in which the pattern transfer and the resist curing are repeatedly performed on the substrate using one mold, if the concave-convex pattern is damaged or blocked during the operation, defects are generated in all subsequent transferred patterns. As a result, a serious decrease in yield may disadvantageously occur.

Hence, in consideration of the problem described above, the present invention aims to improve the yield of the nanoimprint process.

### Solution to Problem

In a nanoimprint liquid material according to one aspect of the present invention, the particle number concentration of particles having a particle diameter of 0.07 μm or more is less than 310/mL.

Further features of the present invention will become apparent from the following description of exemplary embodiments with reference to the attached drawings.

### BRIEF DESCRIPTION OF DRAWINGS

FIG. 1A is a cross-sectional view schematically showing a method for manufacturing a cured product pattern according to one embodiment.

FIG. 1B is a cross-sectional view schematically showing the method for manufacturing a cured product pattern according to the embodiment.

FIG. 1C is a cross-sectional view schematically showing the method for manufacturing a cured product pattern according to the embodiment.

FIG. 1D is a cross-sectional view schematically showing the method for manufacturing a cured product pattern according to the embodiment.

FIG. 1E is a cross-sectional view schematically showing the method for manufacturing a cured product pattern according to the embodiment.

FIG. 1F is a cross-sectional view schematically showing the method for manufacturing a cured product pattern according to the embodiment.

FIG. 1G is a cross-sectional view schematically showing method for manufacturing a cured product pattern according to the embodiment.

FIG. 2A is a view schematically showing the relationship between the particle diameter of a particle and the widths of a concave portion and a convex portion of a pattern of a mold.

FIG. 2B is a view schematically showing the relationship between the particle diameter of the particle and the widths of the concave portion and the convex portion of the pattern of the mold.

FIG. 3A is a view schematically showing a purification system of a nanoimprint liquid material according to one embodiment.

FIG. 3B is a view schematically showing a purification system of a nanoimprint liquid material according to one embodiment.

FIG. 4 is a flowchart showing a method for manufacturing a nanoimprint liquid material according to one embodiment.

FIG. 5A is a view schematically showing a purification system of a nanoimprint liquid material according to one comparative example.

FIG. 5B is a view schematically showing a purification system of a nanoimprint liquid material according to one comparative example.

FIG. 6A is a view schematically showing a purification system of a nanoimprint liquid material according to one example.

FIG. 6B is a view schematically showing a purification system of a nanoimprint liquid material according to one example.

### DESCRIPTION OF EMBODIMENTS

Hereinafter, embodiments of the present invention will be described in detail with reference to appropriate drawings. However, the present invention is not limited at all to the following embodiments. In addition, appropriate modifications, improvements, and the like which are performed on the following embodiments using the general knowledge of a person skilled in the art without departing from the scope of the present invention may also be included in the present invention.

### Nanoimprint Liquid Material

A nanoimprint liquid material (hereinafter simply referred to as “liquid material L”) according to this embodiment is a nanoimprint liquid material in which the particle number concentration of particles having a particle diameter of 0.07 μm or more is less than 310/mL.

The type of liquid material L according to this embodiment is not particularly limited as long as being usable for a nanoimprint process and as long as being a liquid material. In this embodiment, the nanoimprint process is a method in which after a mold having a concave-convex pattern is pressed to a thin film obtained by applying a composition to be cured by heat or light on a substrate, light irradiation or heat treatment is performed so as to form a cured product to which the concave-convex pattern of the mold is transferred. According to the nanoimprint process, for example, a cured product (cured product pattern) having a fine concave-convex pattern of 1 to 100 nm can be formed.

As the liquid material L, for example, (1) a pattern forming curable composition (hereinafter referred to as “composition (1)”), such as a resist forming curable composition or a mold replica forming curable composition, may be mentioned. Alternatively, as the liquid material L, (2) a cured layer forming composition (hereinafter referred to as “composition (2)”), such as an adhesion layer forming composition, an underlayer forming composition, an interlayer forming composition, a topcoat layer forming composition, or a smooth layer forming composition, may be mentioned. However, the type of liquid material L according to this embodiment is not limited to those mentioned above.

In addition, in the present specification, the “cured product” indicates a partially or entirely cured product obtained by polymerizing a polymerizable compound contained in a composition, such as a curable composition. In addition, among the cured products, in particular, a cured product having an extremely small thickness with respect to its area may be emphatically called a “cured film” in some cases. In addition, among the cured films, in particular, a cured film functioning as one of films forming a laminate may be emphatically called a “cured layer” in some cases.

Hereinafter, the liquid material L according to this embodiment will be described in detail.

(Pattern Forming Curable Composition: Composition (1))

In this embodiment, the pattern forming curable composition (composition (1)) is preferably a curable composition containing at least the following component (A) and component (B). However, the composition (1) is not limited to that described above as long as being a composition curable by light irradiation or heat application. For example, the composition (1) may contain a compound having intramolecular reactive functional groups functioning as the component (A) and the component (B).

Component (A): polymerizable component

Component (B): polymerization initiator

Hereinafter, the components of the composition (1) will be described in detail.

<Component (A): Polymerizable Component>

The component (A) is a polymerizable component. The polymerizable component in this embodiment is a component which reacts with polymerization factors (radicals, cations, or the like) generated from the polymerization initiator (component (B)) to form a polymer by a chain reaction (polymerization reaction). The polymerizable component is preferably a component which forms a cured product of a high molecular weight compound by this chain reaction.

The polymerizable component is preferably a component containing a polymerizable compound. In addition, the polymerizable component may be formed of one type of polymerizable compound or at least two types of polymerizable compounds.

In addition, in this embodiment, all the polymerizable compounds contained in the composition (1) are preferably collectively regarded as the component (A). In this case, the structure in which one type of polymerizable compound is only contained in the composition (1) and the structure in which specific plural types of polymerizable compounds are only contained therein may be included.

As the polymerizable compound described above, for example, a radical polymerizable compound or a cationic polymerizable compound may be mentioned. In consideration of reduction in polymerization rate, curing rate, process time, and the like, the polymerizable compound according to this embodiment is more preferably a radical polymerizable compound.

Hereinafter, concrete examples of the radical polymerizable compound and the cationic polymerizable compound will be respectively described.

The radical polymerizable compound is preferably a compound having at least one acryloyl group or methacryloyl group, that is, is preferably a (meth)acrylic compound. That is, when the radical polymerizable compound is used in this embodiment, as the component (A) of the composition (1), a (meth)acrylic compound is preferably contained. In addition, a main component of the component (A) is more preferably a (meth)acrylic compound, and furthermore, all polymerizable compounds contained in the composition (I) are most preferably (meth)acrylic compounds. In addition, the “main component of the component (A) is a (meth)acrylic compound” described above indicates that 90 percent by weight or more of the component (A) is a (meth)acrylic compound.

When the radical polymerizable compound is formed of plural types of (meth)acrylic compounds, a monofunctional (meth)acrylic monomer and a multifunctional (meth)acrylic monomer are preferably contained. The reason for this is that when a monofunctional (meth)acrylic monomer and a multifunctional (meth)acrylic monomer are used in combination, a cured product having a high mechanical strength can be obtained.

As the monofunctional (meth)acrylic compound having one acryloyl group or methacryloyl group, for example, there may be mentioned phenoxyethyl (meth)acrylate, phenoxy-2-methylethyl (methacrylate, phenoxyethoxyethyl (meth)acrylate, 3-phenoxy-2-hydroxypropyl (meth)acrylate, 2-phenyl phenoxyethyl (meth)acrylate, 4-phenyl phenoxyethyl (meth)acrylate, 3-(2-phenylphenyl)-2-hydroxypropyl (meth)acrylate, (meth)acrylate of EO modified p-cumylphenol, 2-boromophenoxyethyl (meth)acrylate, 2,4-diboromophenoxyethyl (meth)acrylate, 2,4,6-triboromophenoxyethyl (meth)acrylate, EO modified phenoxy (meth)acrylate, PO modified phenoxy (meth)acrylate, polyoxyethylene nonylphenyl ether (meth)acrylate, isobornyl (meth)acrylate, 1-adamanthyl (meth)acrylate, 2-methyl-2-adamanthyl (meth)acrylate, 2-ethyl-2-adamanthyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl (meth)acrylate, acryloyl morpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, 1-naphtylmethyl (meth)acrylate, 2-naphtylmethyl (meth)acrylate, tetrahydrofurfuryl (meth)acrylate, butoxyethyl (meth)acrylate, ethoxy diethylene glycol (meth)acrylate, poly(ethylene glycol) mono(meth)acrylate, poly(propylene glycol) mono(meth)acrylate, methoxy ethylene glycol (meth)acrylate, ethoxyethyl (meth)acrylate, methoxy poly(ethylene glycol) (meth)acrylate, methoxy poly(propylene glycol) (meth)acrylate, diacetone (meth)acrylamide, isobutoxymethyl (meth)acrylamide, N,N-dimethyl (meth)acrylamide, t-octyl (meth)acrylamide, dimethyl aminoethyl (meth)acrylate, diethyl aminoethyl (meth)acrylate, 7-amino-3,7-dimethyloctyl (meth)acrylate, N,N-diethyl (meth)acrylamide, and N,N-dimethyl aminopropyl (meth)acrylamide. However, the monofunctional (meth)acrylic compound is not limited to those mentioned above.

As a commercially available product of the above monofunctional (meth)acrylic compound, for example, there may be mentioned Aronix M101, M102, M110, M111, M113, M117, M5700, TO-1317, M120, M150, and M156 (manufactured by Toagosei Co., Ltd); MEDOL10, MIBDOL10, CHDOL10, MMDOL30, MEDOL3O, MIBDOL30, CHDOL30, LA, IBXA, 2-MTA, HPA, Viscoat #150, #155, #158, #190, #192, #193, #220, #2000, #2100, and #2150 (manufactured by Osaka Organic Industry Ltd.); Light Acrylate BO-A, EC-A, DMP-A, THE-A, HOP-A, HOA-MPE, HOA-MPL, PO-A, P-200A, NP-4EA, NP-BEA, and Epoxy Ester M-600A (manufactured by Kyoeisha Chemical Co., Ltd.); KAYARAD TC110S, R-564, and R-128H (manufactured by Nippon Kaya.ku Co., Ltd.); NK Ester AMP-10G and AMP-20G (manufactured by Shin-Nakamura Chemical Co., Ltd.); FA-511A, 512A, and 513A (manufactured by Hitachi Chemical Co., Ltd.); PHE, CEA, PHE-2, PHE-4, BR-31, BR-31M, and BR-32 (manufactured by Dai-ichi Kogyo Seiyakyu Co., Ltd.); VP (manufactured by BASF); and ACMO, DMAA, and DMAPAA (manufactured by Kohjin Co., Ltd.). However, the commercially available product of the above mono-functional (meth)acrylic compound is not limited to those mentioned above.

As the multifunctional (meth)acrylic compound having at least two acryloyl groups or methacryloyl groups, for example, there may be mentioned trimethylolpropane di(meth)acrylate, trimethylolpropane tri(meth)acrylate, EO-modified trimethylolpropane tri(meth)acrylate, PO-modified trimethylolpropane tri(meth)acrylate, EO, PO-modified trimethylolpropane tri(meth)acrylate, dimethyloltricyclodecane di(meth)acrylate, pentaerythritol tri(meth)acrylate, pentaerythritol tetra(meth)acrylate, ethylene glycol di(meth)acrylate, tetraethylene glycol di(meth)acrylate, phenylethylene glycol di(meth)acrylate, poly(ethylene glycol) di(meth)acrylate, polypropylene glycol) di(meth)acrylate, 1,4-butanediol di(meth)acrylate,1,6-hexanediol di(meth)acrylate, neopentyl glycol di(meth)acrylate, 1,9-nonanediol di(meth)acrylate, 1,10-decanediol di(meth)acrylate, 1,3-adamantanedimethanol di(meth)acrylate, o-xylylene di(meth)acrylate, m-xylylene di(meth)acrylate, p-xylylene di(meth)acrylate, tris(2-hydroxyethyl)isocyanurate tri(meth)acrylate, tris(acryloyloxy)isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acyloxy)phenyl)propane, PO-modified 2,2-bis(4-((meth)acyloxy)phenyl)propane, and EO, PO-modified 2,2-bis(4-((meth)acyloxy)phenyl)propane. However, the multifunctional (meth)acrylic compound is not limited to those mentioned above.

As a commercially available product of the above multifunctional (meth)acrylic compound, for example, there may be mentioned. Yupimer UV SA1002 and SA2007 (manufactured by Mitsubishi Chemical Corp.); Viscoat #1.95, #230, #215, #260, #335HP, #295, #300, #360, #700, OPT, and 3PA (manufactured by Osaka Organic Chemical industry, Ltd.); Light Acrylate 4EG-A, 9EG-A, NP-A, DCP-A, BP-4EA, BP-4PA, TMP-A, PE-3A, PE-4A, and DPE-6A (manufactured by Kyoeisha Chemical Co., Ltd.); KAYARAD PET-30, TMPTA, R-604, DPHA, DPCA-20, -30, -60, -120, HX-620, D-310, and D-330 (manufactured by Nippon Kayaku Co., Ltd.); Aronix M208, M210, M215, M220, M240, M305, M309, M310, M315, M325, and M400 (manufactured by Toagosei Co., Ltd.); and Ripoxy VR-77, VR-60, and VR-90 (manufactured by Showa Denko K.K.). However, the commercially available product of the above multifunctional (meth)acrylic compound is not limited to those mentioned above.

Those radical polymerizable compounds may be used alone, or at least two types thereof may be used in combination. In the compound groups mentioned above, the (meth)acrylate indicates an acrylate or a methacrylate having an alcohol residue equivalent to that thereof. The (meth)acryloyl group indicates an acryloyl group or a methacryloyl group having an alcohol residue equivalent to that thereof. The “EO” indicates ethylene oxide, and an EO-modified compound A indicates a compound in which a (meth)acrylic acid residue and an alcohol residue of the compound A are bonded to each other with a block structure formed of at least one ethylene oxide group provided therebetween. In addition, the “PO” indicates propylene oxide, and an PO-modified compound B indicates a compound in which a (meth)acrylic acid residue and an alcohol residue of the compound B are bonded to each other with a block structure formed of at least one propylene oxide group provided therebetween.

In addition, as the cationic polymerizable compound, a compound having at least one of a vinyl ether group, an epoxy group, and an oxetanyl group is preferable.

Accordingly, when the cationic polymerizable compound is used in this embodiment, as the component (A) of the composition (I), a compound containing a vinyl ether group, an epoxy group, or an oxetanyl group is preferably contained. In addition, the main component of the component (A) is more preferably a compound having a vinyl ether group, an epoxy group, or an oxetanyl group. Furthermore, all the polymerizable compounds contained in the composition (1) are most preferably compounds each having a vinyl ether group, an epoxy group, or an oxetanyl group. In addition, the “main component of the component (A) is a compound having a vinyl ether group, an epoxy group, or an oxetanyl group” described above indicates that 90 percent by weight or more of the component (A) is a compound having a vinyl ether group, an epoxy group, or an oxetanyl group.

When the cationic polymerizable compound is formed of plural types of compounds each containing at least one of a vinyl ether group, an epoxy group, and an oxetanyl group, a monofunctional monomer and a multifunctional monomer are preferably contained. The reason for this is that when a monofunctional monomer and a multi-functional monomer are used in combination, a cured product having a high mechanical strength can be obtained.

As a compound having one vinyl ether group, for example, there may be mentioned methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexylmethyl vinyl ether, 4-methylcyclohexylmethyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxy(polyethylene glycol) vinyl ether, tetrahydrofurfuryl vinyl ether, 2-hydroxyethyl vinyl ether, 2-hydroxypropyl vinyl ether, 4-hydroxybutyl vinyl ether, 4-hydroxymethylcyclohexylmethyl vinyl ether, diethylene glycol monovinyl ether, polyethylene glycol) vinyl ether, chloroethyl vinyl ether, chlorobutyl vinyl ether, chloroethoxyethyl vinyl ether, phenylethyl vinyl ether, and phenoxy(polyethylene glycol) vinyl ether. However, the compound having one vinyl ether group is not limited to those mentioned above.

As a compound having at least two vinyl ether groups, for example, there may be mentioned divinyl ethers, such as ethylene glycol divinyl ether, diethylene glycol divinyl ether, poly(ethylene glycol) divinyl ether, propylene glycol divinyl ether, butylene glycol divinyl ether, hexanediol divinyl ether, bisphenol A alkylene oxide divinyl ether, and bisphenol F alkylene oxide divinyl ether; and multifunctional vinyl ethers, such as trimethylolethane trivinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexa vinyl ether, ethylene oxide adduct trimethylolpropane trivinyl ether, propylene oxide adduct trimethylolpropane trivinyl ether, ethylene oxide adduct ditrimethylolpropane tetravinyl ether, propylene oxide adduct ditrimethylolpropane tetravinyl ether, ethylene oxide adduct pentaerythritol tetravinyl ether, propylene oxide adduct pentaerythritol tetravinyl ether, ethylene oxide adduct dipentaerythritol hexavinyl ether, and propylene oxide adduct dipentaerythritol hexavinyl ether. However, the compound having at least two vinyl ether groups is not limited to those mentioned above.

As a compound having one epoxy group, for example, there may be mentioned phenyl glycidyl ether, p-tert-butylphenyl glycidyl ether, butyl glycidyl ether, 2-ethylhexyl glycidyl ether, allyl glycidyl ether, 1,2-butylene oxide, 1,3-butadiene monooxide, 1,2-epoxydodecane, epichlorohydrin, 1,2-epoxydecane, styrene oxide, cyclohexene oxide, 3-methacryloyloxymethylcyclohexene oxide, 3-acryloyloxymethylcyclohexene oxide, and 3-vinyl cyclohexene oxide. However, the compound having one epoxy group is not limited to those mentioned above.

As a compound having at least two epoxy groups, for example, there may be mentioned bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, epoxy novolac resin, hydrogenated bisphenol A diglycidyl ether, hydrogenated bisphenol F diglycidyl ether, hydrogenated bisphenol S diglycidyl ether, 3,4-epoxycyclohexylmethyl-3′,4′-epoxycyclohexane carboxylate, 2-(3,4-epoxycyclohexyl-5,5-spiro-3,4-epoxy)cyclohexane-meta-dioxane, bis(3,4-epoxycyclohexylmethyl)adipate, vinyl cyclohexene oxide, 4-vinyl epoxycyclohexane, bis(3,4-epoxy-6-methylcyclohexylmethyl)adipate, 3,4-epoxy-6-methylcyclohexyl-3′,4′-epoxy-6′-methylcyclohexane carboxylate, methylene bis(3,4-epoxycyclohexane), dicyclopentadiene diepoxide, di(3,4-epoxycyclohexylmethyl) ether of ethylene glycol, ethylene bis(3,4-epoxycyclohexane carboxylate), dioctyl epoxyhexahydrophthalate, di-2-ethylhexyl epoxyhexahydrophthalate, 1,4-butanediol diglycidyl ether, 1,6-hexanediol diglycidyl ether, glycerin triglycidyl ether, trimethylolpropane triglycidyl ether, poly(ethylene glycol) diglycidyl ether, poly(propylene glycol) diglycidyl ether, 1,1,3-tetradecadiene dioxide, limonene dioxide, 1,2,7,8-diepoxyoctane, and 1,2,5,6-diepoxycyclooctane. However, the compound having at least two epoxy groups is not limited to those mentioned above.

As a compound having one oxetanyl group, for example, there may be mentioned 3-ethyl-3-hydroxymethyloxetane, 3-(meth)allyloxymethyl-3-ethyloxetane, (3-ethyl-3-oxetanylmethoxy)methylbenzene, 4-fluoro-[1-(3-ethyl-3-oxetanylmethoxy)methyl]benzene, 4-methoxy-[1-(3-ethyl-3-oxetanylmethoxy)methyl]benzene, [1-(3-ethyl-3-oxetanylmethoxy)ethyl]phenyl ether, isobutoxymethyl (3-ethyl-3-oxetanylmethyl) ether, isobomyloxyethyl (3-ethyl-3-oxetanylmethyl) ether, isobornyl (3-ethyl-3-oxetanylmethyl) ether, 2-ethylhexyl (3-ethyl-3-oxetanylmethyl) ether, ethyldiethylene glycol (3-ethyl-3-oxetanylmethyl) ether, dicyclopentadiene (3-ethyl-3-oxetanylinethyl) ether, dicyclopentenyloxyethyl (3-ethyl-3-oxetanylmethyl) ether, dicyclopentenyl (3-ethyl-3-oxetanylmethyl) ether, tetrahydrofurfuryl (3-ethyl-3-oxetanylmethyl) ether, tetrabromophenyl (3-ethyl-3-oxetanylmethyl) ether, 2-tetrabromophenoxyethyl (3-ethyl-3-oxetanylmethyl) ether, tribromophenyl (3-ethyl-3-oxetanylmethyl) ether, 2-tribromophenoxyethyl (3-ethyl-3-oxetanylmethyl) ether, 2-hydroxyethyl (3-ethyl-3-oxetanylmethyl) ether, 2-hydroxypropyl (3-ethyl-3-oxetanylmethyl) ether, butoxyethyl (3-ethyl-3-oxetanylmethyl) ether, pentachlorophenyl (3-ethyl-3-oxetanylmethyl) ether, pentabromophenyl (3-ethyl-3-oxetanylmethyl) ether, and bornyl (3-ethyl-3-oxetanylmethyl) ether. However, the compound having one oxetanyl group is not limited to those mentioned above.

As a compound having at least two oxetanyl groups, for example, there may be mentioned 3,7-bis(3-oxetanyl)-5-oxa-nonane, 3,3′-(1,3-(2-methylenyl)propanediyl bis(oxymethylene))bis-(3-ethyloxetane), 1,4-bis[(3-ethyl-3-oxetanylmethoxy)methyl]benzene, 1,2-bis[(3-ethyl-3-oxetanylmedioxy)methyl]ethane, 1,3-bis[(3-ethyl-3-oxetanylinethoxy)methyl]propane, ethylene glycol bis(3-ethyl-3-oxetanylmethyl) ether, dicyclopentenyl bis(3-ethyl-3-oxetanylmethyl) ether, triethylene glycol bis(3-ethyl-3-oxetanylmethyl) ether, tetraethylene glycol bis(3-ethyl-3-oxetanylmethyl) ether, tricyclodecanediyl dimethylene(3-ethyl-3-oxetanylmethyl) ether, trimethylolpropane tris(3-ethyl-3-oxetanylmethyl) ether, 1,4-bis(3-ethyl-3-oxetanylmethoxy)butane, 1,6-bis(3-ethyl-3-oxetanylmethoxy)hexane, pentaerythritol tris(3-ethyl-3-oxetanylmethyl) ether, pentaerythritol tetrakis(3-ethyl-3-oxetanylmethyl) ether, poly(ethylene glycol) bis(3-ethyl-3-oxetanylmethyl) ether, dipentaerythritol hexakis(3-ethyl-3-oxetanylmethyl) ether, dipentaerythritol pentakis(3-ethyl-3-oxetanylmethyl) ether, dipentaerythritol tetrakis(3-ethyl-3-oxetanylmethyl) ether, caprolactone-modified dipentaerythritol hexakis(3-ethyl-3-oxetanylmethyl) ether, caprolactone-modified dipentaerythritol pentakis(3-ethyl-3-oxetanylmethyl) ether, ditrimethylolpropane tetrakis(3-ethyl-3-oxetanylmethyl) ether, EO-modified bisphenol A bis(3-ethyl-3-oxetanylmethyl) ether, PO-modified bisphenol A his(3-ethyl-3-oxetanylmethyl) ether, EO-modified hydrogenated bisphenol A bis(3-ethyl-3-oxetanylmethyl) ether, PO-modified hydrogenated bisphenol A bis(3-ethyl-3-oxetanylmethyl) ether, and EO-modified bisphenol F (3-ethyl-3-oxetanylmethyl) ether. However, the compound having at least two oxetanyl groups is not limited to those mentioned above.

Those cationic polymerizable compounds may be used alone, or at least two types thereof may be used in combination. In addition, among the compound groups mentioned above, the “EO” indicates ethylene oxide, and the EO modified compound indicates a compound having a block structure formed of at least one ethylene oxide group. In addition, the “PO” indicates propylene oxide, and the PO modified compound indicates a compound having a block structure formed of at least one propylene oxide group. Furthermore, the “hydrogenated” indicates the state in which at least one hydrogen atom is added to a C═C double bond of benzene or the like.

<Component (B): Polymerization Initiator>

The component (B) is a polymerization initiator. As the polymerization initiator according to this embodiment, for example, there may be mentioned a photopolymerization initiator which is a compound generating polymerization factors by light and a thermal polymerization initiator which is a compound generating polymerization factors by heat.

The component (B) may be formed of one type of polymerization initiator or may be formed of plural types of polymerization initiators. In addition, the component (B) may be formed of both a photopolymerization initiator and a thermal polymerization initiator.

The photopolymerization initiator is a compound which generates the above polymerization factors (such as radicals or cations) when detecting light having a predetermined wavelength (infrared rays, visible light rays, ultraviolet rays, deep ultraviolet rays, X-rays, charged particle rays such as electron rays, radioactive rays, or the like). In particular, as the photopolymerization initiator, for example, a photoradical generator generating radicals by light and a photo-acid generator generating protons (H⁺) by light may be mentioned. The photoradical generator is primarily used when the polymerizable component (A) contains a radical polymerizable compound. On the other hand, the photo-acid generator is primarily used when the polymerizable component (A) contains a cationic polymerizable compound. As the photoradical generator, for example, there play be mentioned 2,4,5-triarylimidazole dimer which may have a substitute, such as 2-(o-chlorophenyl)-4,5-diphenylimidazole dimer, 2-(o-chlorophenyl)-4,5-di(methoxyphenyl)imidazole dimer, 2-(o-fluorophenyl)-4,5-diphenylimidazole dimer, or 2-(o- or p-methoxyphenyl)-4,5-diphenylimidazole dimer; a benzophenone derivative, such as benzophenone, N,N′-tetramethyl-4,4′-diaminobenzophenone (Michlers ketone), N,N′-tetraethyl-4,4′-diaminobenzophenone, 4-methoxy-4′-dimethylaminobenzophenone, 4-chlorobenzophenone, 4,4′-dimethoxybenzophenone, or 4,4′-diaminobenzophenone; an α-aminoaromatic ketone derivative, such as 2-benzyl-2-dimethylamino-1-(4-morpholine-phenyl)-butanone-1 or 2-methyl-1-[4-(methylthio)phenyl]-2-morpholino-propane-1-one; a quinone derivative, such as 2-ethylanthraquinone, phenanthrenequinone, 2-tert-butyl-anthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthaquinone, 9,10-phenathraquinone, 2-methyl-1,4-naphthoquinone, or 2,3-dimethylanthraquinone; a benzoin ether derivative, such as benzoin methyl ether, benzoin ethyl ether, or benzoin phenyl ether; a benzoin derivative, such as benzoin, methylbenzoin, ethylbenzoin, or propylbenzoin; a benzyl derivative, such as benzyl methyl ketal; an acridine derivative, such as 9-phenylacridine or 1,7-bis(9,9′-acridinyl)heptane; a N-phenylglycine derivative, such as N-phenylglycine; an acetophenone derivative, such as acetophenone, 3-methylacetophenone, acetophenone benzyl ketal, 1-hydroxycyclohexyl phenyl ketone, or 2,2-dimethoxy-2-phenylacetophenone; a thioxanthone derivative, such as thioxanthone, diethylthioxanthone, 2-isopropylthioxanthone, or 2-chlorothioxanthone; an acylphosphine oxide derivative, such as 2,4,6-trimethylbenzoyl diphenylphosphine oxide, bis(2,4,6-trimethylbenzoyl)phenylphosphine oxide, or bis(2,6-dimethoxybenzoyl)-2,4,4-trimethylpentylphosphine oxide; an oxime ester derivative, such as 1,2-octanedione, 1[4-(phenylthio)-2-(o-benzoyloxime)]or ethanone, 1-[9-ethyl-6-(2-methylbenzoyl)-9H-carbazol-3-yl], 1-(o-acetyl oxime); xanthene, fluorenone, benzaldehyde, fluorene, anthraquinone, triphenylamine, carbazole, 1-(4-isopropylphenyl)-2-hydroxy-2-methylpropane-1-one, or 2-hydroxy-2-methyl-1-phenylpropane-1-one. However, the photoradical generator is not limited to those mentioned above.

As a commercially available product of the photoradical generator mentioned above, for example, Irgacure 184, 369, 651, 500, 819, 907, 784, 2959, CGI-1.700, -1750, -1850, CG24-61, Darocur 1116, 1173, Lucirin TPO, LR8893, and LR8970 (manufactured by BASF); and Ubecryl P36 (manufactured by UCB) may be mentioned. However, the commercially available products of the photoradical generator are not limited to those mentioned above.

Among those compounds mentioned above, as the photoradical generator, an acylphosphine oxide polymerization initiator or an alkylphenone polymerization initiator is preferable. Among the examples mentioned above, the acylphosphine oxide polymerization initiator is an acylphosphine oxide compound, such as 2,4,6-trimethylbenzoyl diphenylphosphine oxide, bis(2,4,6-trimethylbenzoyl)phenylphosphine oxide, or bis(2,6-dimethoxybenzoyl)-2,4,4-trimethylpentylphosphine oxide. In addition, among the examples mentioned above, the alkylphenone polymerization initiator is a benzoin ether derivative, such as benzoin methyl ether, benzoin ethyl ether, or benzoin phenyl ether; a benzoin derivative, such as benzoin, methylbenzoin, ethylbenzoin, or propylbenzoin; a benzyl derivative, such as benzyl methyl ketal; an acetophenone derivative, such as acetophenone, 3-methylacetophenone, acetophenone benzyl ketal, 1-hydroxycyclohexyl phenyl ketone, or 2,2-dimethoxy-2-phenylacetophenone; or an α-aminoaromatic ketone derivative, such as 2-benzyl-2-dimethylamino-1-(4-morpholino-phenyl)-butanone-1 or 2-methyl-1-[4-(methylthio)phenyl]-2-morpholino-propane-1-one.

As the photo-acid generator, for example, there may be mentioned an onium salt compound, a sulfone compound, a sulfonic acid ester compound, a sulfone imide compound, and a diazomethane compound may be mentioned. However, the photoacid generator is not limited to those mentioned above. In the present invention, an onium salt compound is preferable.

As the onium salt compound, for example, an iodonium salt, a sulfonium salt, a phosphonium salt, a diazonium salt, an ammonium salt, and a pyridium salt may be mentioned.

As the onium salt compound, for example, there may be mentioned bis(4-tert-butylphenyl)iodonium perfluoro-n-butanesulfonate, bis(4-tert-butylphenyl)iodonium trifluoromethanesulfonate, bis(4-tert-butylphenyl)iodonium 2-trifluoromethylbenzenesulfonate, bis(4-tert-butylphenyl)iodonium pyrenesulfonate, bis(4-tert-butylphenyl)iodonium n-dodecylbenzenesulfonate, bis(4-tert-butylphenyl)iodonium p-toluenesulfonate, bis(4-tert-butylphenyl)iodonium benzenesulfonate, bis(4-tert-butylphenyl)iodonium 10-camphorsulfonate, bis(4-tent-butylphenyl)iodonium n-octanesulfonate, diphenyliodonium perfluoro-n-butanesulfonate, diphenyliodonium trifluoromethane-sulfonate, diphenyliodonium 2-trifluoromethylbenzenesulfonate, diphenyliodonium pyrenesulfonate, diphenyliodonium n-dodecylbenzenesulfonate, diphenyliodonium p-toluenesulfonate, diphenyliodonium benzenesulfonate, diphenyliodonium 10-camphorsulfonate, diphenyliodonium n-octanesulfonate, triphenylsulfonium perfluoro-n-butanesulfonate, triphenylsulfonium trifluoromethanesulfonate, triphenyl-sulfonium 2-trifluoromethylbenzenesulfonate, triphenylsulfonium pyrenesulfonate, triphenylsulfonium n-dodecylbenzenesulfonate, triphenylsulfonium p-toluenesulfonate, triphenylsulfonium benzenesulfonate, triphenylsulfonium 10-camphorsulfonate, triphenylsulfonium n-octanesulfonate, diphenyl(4-tert-butylphenyl)sulfonium perfluoro-n-butanesulfonate, diphenyl(4-tort-butylphenyl)sulfonium trifluoromethanesulfonate, diphenyl(4-tert-butylphenyl)sulfonium 2-trifluoromethylbenzenesulfonate, diphenyl(4-tert-butylphenyl)sulfonium pyrenesulfonate, diphenyl(4-tert-butylphenyl)sulfonium n-dodecylbenzenesulfonate, diphenyl(4-tert-butylphenyl)sulfonium p-toluenesulfonate, diphenyl(4-tert-butylphenyl)sulfonium benzenesulfonate, diphenyl(4-tert-butylphenyl)sulfonium 10-camphorsulfonate, diphenyl(4-tert-butylphenyl)sulfonium n-octanesulfonate, tris(4-methoxyphenyl)sulfonium perfluoro-n-butanesulfonate, tris(4-methoxyphenyl)sulfonium trifluoromethanesulfonate, tris(4-methoxyphenyl)sulfonium 2-trifluoromethylbenzenesulfonate, tris(4-methoxyphenyl)sulfonium pyrenesulfonate, tris(4-methoxyphenyl)sulfonium n-dodecylbenzenesulfonate, tris(4-methoxyphenyl)sulfonium p-toluenesulfonate, tris(4-methoxyphenyl)sulfonium benzenesulfonate, tris(4-methoxyphenyl)sulfonium 10-camphorsulfonate, or tris(4-methoxyphenyl)sulfonium n-octanesulfonate. However, the onium salt compound is not limited to those mentioned above.

As the sulfone compound, for example, there may be mentioned a β-ketosulfone, a β-sulfonyl sulfone, or an α-diazo compound thereof. As a concrete example of the sulfone compound, for example, phenacyl phenylsulfone, mesitylphenacyl sulfone, bis(phenyl sulfonyl)methane, or 4-trisphenancyl sulfone may be mentioned; however, the sulfone compound is not limited to those mentioned above.

As the sulfonic acid ester compound, for example, an alkylsulfonate ester, a haloalkyl sulfonate ester, an aryl sulfonate ester, or an imino sulfonate may be mentioned. As a concrete example of the sulfonate ester compound, for example, α-methylolbenzoin perfluoro-n-butanesulfonate, α-methylolbenzoin trifluoromethanesulfonate, or α-methylolbenzoin 2-trifluoromethylbenzenesulfonate may be mentioned; however, the sulfonate ester compound is not limited to those mentioned above.

As the sulfone imide compound, for example, there may be mentioned N-(trifluoromethylsulfonyloxy)succinimide, N-(trifluoromethylsulfonyloxy)phthalimide, N-(trifluoromethylsulfonyloxy)diphenylmaleimide, N-(trifluoromethylsulfonyloxy)bicyclo[2.2.1]hepto-5-ene-2,3-dicarboxyimide, N-(trifluoromethylsulfonyloxy)-7-oxabicyclo[2.2.1]hepto-5-ene-2,3-dicarboxyimide, N-(trifluoromethylsulfonyloxy)bicyclo[2.2.1]heptane-5,6-oxy-2,3-dicarboxyimide, N-(trifluoromethylsulfonyloxy)naphthylimide, N-(10-camphorsulfonyloxy)succinimide, N-(10-camphorsulfonyloxy)phthalimide, N-(10-camphorsulfonyloxy)diphenylmaleimide, N-(10-camphorsulfonyloxy)bicyclo[2.2.1]hepto-5-ene-2,3-dicarboxyimide, N-(10-camphorsulfonyloxy)-7-oxabicyclo[2.2.1]hepto-5-ene-2,3-dicarboxylmide, N-(10-camphorsulfonyloxy)bicyclo[2.21]heptane-5,6-oxy-2,3-dicarboxylmide, N-(10-camphorsulfonyloxy)naphthylimide, N-(4-methylphenylsulfonyloxy)succinimide, N-(4-methylphenylsulfonyloxy)phthalimide, (4-methylphenylsulfonyloxy)diphenylmaleimide, N-(4-methylphenylsulfonyloxy)bicyclo[2.2.1]hepto-5-ene-2,3-dicarboxyimide, N-(4-methylphenylsulfonyloxy)-7-oxabicyclo[2.2.1]hepto-5-ene-2,3-dicarboxyimide, N-(4-methylphenylsulfonyloxy)bicyclo[2.2.1]heptane-5,6-oxy-2,3-dicarboxyimide, N-(4-methylphenylsulfonyloxy)naphthylimide, N-(2-trifluoromethylphenylsulfonyloxy)succinimide, N-(2-trifluoromethylphenylsulfonyloxy)phthalimide, N-(2-trifluoromethylphenylsulfonyloxy)diphenylmaleimide, N-(2-trifluoromethylphenylsulfonyloxy)bicyclo[2.2.1]hepto-5-ene-2,3-dicarboxyimide, N-(2-trifluoromethylphenylsulfonyloxy)-7-oxabicyclo[2.2.1]hepto-5-ene-2,3-dicarboxyimide, N-(2-trifluoromethylphenylsulfonyloxy)bicyclo[2.2.1]heptane-5,6-oxy-2,3-dicarboxyimide, N-(2-trifluoromethylphenylsulfonyloxy)naphthylimide, N-(4-fluorophenylsulfonyloxy)succinimide, N-(4-fluorophenylsulfonyloxy)phthalimide, N-(4-fluorophenylsulfonyloxy)diphenylmaleimide, N-(4-fluorophenylsulfonyloxy)bicyclo[2.2.1]hepto-5-ene-2,3-dicarboxyimide, N-(4-fluorophenylsulfonyloxy)-7-oxabicyclo[2.2.1]hepto-5-ene-2,3-dicarboxyimide, N-(4-fluorophenylsulfonyloxy)bicyclo[2.2.1]heptane-5,6-oxy-2,3-dicarboxyimide, or N-(4-fluorophenylsulfonyloxy)naphthylimide. However, the sulfone imide compound is not limited to those mentioned above.

As the diazomethane compound, for example, there may be mentioned bis(trifluoromethylsulfonyl)diazomethane, bis(cyclohexylsulfonyl)diazomethane, bis(phenylsulfonyl)diazomethane, bis(p-toluenesulfonyl)diazomethane, methylsulfonyl p-toluenesulfonyl diazomethane, (cyclohexylsulfonyl)(1,1-dimethylethylsulfonyl)diazomethane, or bis (1,1-dimethylethylsulfonyl)diazomethane; however, the diazomethane compound is not limited to those mentioned above.

The thermal polymerization initiator is a compound generating the polymerization factors (radicals, cations, or the like) by heat. In particular, as the thermal polymerization initiator, for example, a thermal radical generator generating radicals by heat or a thermal acid generator generating protons (H⁺) by heat may be mentioned. The thermal radical generator is primarily used when the polymerizable component (A) contains a radical polymerizable compound. On the other hand, the thermal acid generator is primarily used when the polymerizable component (A) contains a cationic polymerizable compound.

As the thermal radical generator, for example, an organic peroxide and an azo compound may be mentioned. As the organic peroxide, for example, there may be mentioned a peroxy ester, such as t-hexyl peroxy isopropyl monocarbonate, t-hexyl peroxy-2-ethyl hexanoate, t-butyl peroxy-3,5,5-trimethyl hexanoate, or t-butylperoxy isopropyl carbonate; a peroxy ketal such as 1,1-bis(t-hexyl peroxy)-3,3,5-trimethylcyclohexane; or a diacyl peroxide such as lauroyl peroxide; however, the organic peroxide is not limited to those mentioned above. In addition, as the azo compound, although an azo nitrile, such as 2,2′-azobisisobutyronitrile, 2,2′-azobis(2-methylbutyronitrile), or 1,1′-azobis(cyclohexane-1-carbonitrile) may be mentioned, the azo compound is not limited thereto.

As the thermal acid generator, for example, a known iodonium salt, sulfonium salt, phosphonium salt, or ferrocene may be mentioned. In particular, for example, there may be mentioned, but not limited to, diphenyliodonium hexafluoroantimonate, diphenyliodonium hexafluorophosphate, diphenyliodonium hexafluoroborate, triphenylsulfonium hexafluoroantimonate, triphenylsulfonium hexafluorophosphate, or triphenylsulfonium hexafluoroborate.

The blending rate of the component (B) functioning as the polymerization initiator in the composition (I) is, with respect to the total of the component (A) which is the polymerizable component, 0.01 to 10 percent by weight and preferably 0.1 to 7 percent by weight.

When the blending rate of the component (B) to the total of the component (A) is set to 0.01 percent by weight or more, the curing rate of the composition (1) can be increased. As a result, the reaction efficiency can be improved. In addition, when the blending rate of the component (B) to the total of the component (A) is set to 10 percent by weight or less, a cured product to be obtained is able to have a certain mechanical strength.

<Other Addition Components (C)>

Besides the component (A) and the component (B), in accordance with various purposes, the composition (1) according to this embodiment may also contain at least one addition component (C) without degrading the advantage of the present invention. As the addition component (C) described above, for example, a sensitizer, a hydrogen donor, an internal addition type mold release agent, a surfactant, an antioxidant, a solvent, a polymer component, and a polymerization initiator other than the above component (B) may be mentioned.

In order to promote a polymerization reaction and to improve a reaction conversion rate, the sensitizer is a compound to be appropriately added. As the sensitizer, for example, a sensitizing dye may be mentioned.

The sensitizing dye is a compound which is excited by absorption of light having a specific wavelength and which interacts with the component (B) functioning as the photopolymerization initiator. In addition, the interaction described above indicates energy transfer, electron transfer, or the like from an excited sensitizing dye to the component (B) functioning as the photopolymerization initiator.

As a concrete example of the sensitizing dye, for example, there may be mentioned, but not limited to, an anthracene derivative, an anthraquinone derivative, a pyrene derivative, a perylene derivative, a carbazole derivative, a benzophenone derivative, a thioxanthone derivative, a xanthone derivative, a coumarin derivative, a phenothiazine derivative, a camphorquinone derivative, an acridine dye, thiopyrylium salt dye, a merocyanine dye, a quinoline dye, a styrylquinoline dye, a ketocoumarin dye, a thioxanthene dye, a xanthene dye, an oxonol dye, a cyanine dye, a rhodamine dye, or a pyrylium salt dye.

The sensitizers may be used alone, or at least two types thereof may be used in combination.

The hydrogen donor is a compound generating radicals having a higher reactivity by a reaction with initiation radicals generated from the component (B) and/or with radicals of polymerization growth terminates. The hydrogen donor is preferably added when the component (B) is a photoradical generator or a thermal radical generator.

As an concrete example of the hydrogen donor described above, for example, there may be mentioned an amine compound, such as n-butylamine, di-n-butylamine, tri-n-butylainine, allylthiourea, s-benzyl isothiuronium-p-toluenesulfinate, triethylamine, diethylaminoethyl methacrylate, triethylenetetramine, 4,4′-bis(dialkylamino)benzophenone, ethyl N,N-dimethelaminobenzoate, isoamyl N,N-dimethylaminobenzoate, pentyl-4-dimethylaminobenzoate, triethanolamine, or N-phenylglycine; or a mercapto compound, such as 2-mercapto-N-phenylbenzimidazole or mercapto propionate.

The hydrogen donors may be used alone, or at least two types thereof may be used in combination.

When the composition (1) according to this embodiment contains a sensitizer and a hydrogen donor as the addition components (C), the contents thereof are each preferably 0 to 20 percent by weight with respect to the total of the component (A). In addition, the contents thereof are each preferably 0.1 to 5.0 percent by weight and more preferably 0.2 to 2.0 percent by weight. When 0.1 percent by weight or more of the sensitizer is contained with respect to the total of the component (A), the polymerization promotion effect can be more effectively obtained. In addition, when the content of the sensitizer or the hydrogen donor is set to 5.0 percent by weight or less with respect to the total of the component (A), the molecular weight of a high molecular weight compound forming a cured product can be sufficiently increased. Furthermore, insufficient dissolution of the sensitizer or the hydrogen donor into the composition (1) and/or degradation in storage stability thereof can be suppressed.

In order to reduce the interface bonding force between a mold and a resist, that is, in order to reduce a releasing force in the mold release step which will be described later, an internal addition type mold release agent may be added into the composition (1). In this case, the “internal addition type mold release agent” of the present specification indicates a mold release agent to be added to the composition (1) in advance before the arrangement step which will be described below is performed.

As the internal addition type mold release agent, for example, a surfactant, such as a silicone-based surfactant, a fluorine-based surfactant, or a hydrocarbon-based surfactant, may be used. In this embodiment, the internal addition type mold release agent has no polymerizing properties.

The fluorine-based surfactant may include a poly(alkylene oxide) (such as a poly(ethylene oxide) or a poly(propylene oxide)) adduct of an alcohol having a perfluoroalkyl group or a poly(alkylene oxide) (such as a poly(ethylene oxide) or a poly(propylene oxide)) adduct of a perfluoropolyether. In addition, the fluorine-based surfactant may have a hydroxyl group, an alkoxy group, an alkyl group, an amino group, a thiol group, or the like at a part (such as a terminal group) of its molecular structure.

As the fluorine-based surfactant, a commercially available product may also be used. As the commercially available fluorine-based surfactant, for example, there may be. mentioned, but not limited to, MEGAFAC F-444, TF-2066, TF-2067, and TF-2068 (manufactured by DIC); Fluorad FC-430 and FC-431 (manufactured by Sumitomo 3M Limited); SURFLON S-382 (manufactured by AGC); EFTOP EF-122A, 122B, 122C, EF-121, EF-126, EF-127, and MF-100 (manufactured by Tohkem Products Corp.); PF-636, PF-6320, PF-656, and PF-6520 (manufactured by OMNOVA Solutions, Inc.); UNIDYNE DS-401, DS-403, and DS-451 (manufactured by DAIKIN INDUSTRIES, LTD); and Ftergent 250, 251, 222F, and 208G (manufactured by Neos).

The hydrocarbon-based surfactant may include an alkyl alcohol poly(alkylene oxide) adduct in which an alkylene oxide having 2 to 4 carbon atoms is added to an alkyl alcohol having 1 to 50 carbon atoms.

As the alkyl alcohol poly(alkylene oxide) adduct, for example, a methyl alcohol ethylene oxide adduct, a decyl alcohol ethylene oxide adduct, a lauryl alcohol ethylene oxide adduct, a cetyl alcohol ethylene oxide adduct, a stearyl alcohol ethylene oxide adduct, or a stearyl alcohol ethylene oxide/propylene oxide adduct may be mentioned. In addition, the terminal group of the alkyl alcohol poly(alkylene oxide) is not limited to a hydroxyl group which is simply manufactured by adding a poly(alkylene oxide) to an alkyl alcohol. This hydroxyl group may be substituted by another substitution group, for example, by a polar functional group, such as a carboxyl group, an amino group, a pyridyl group, a thiol group, or a silanol group, or a hydrophobic functional group, such as an alkyl group or an alkoxy group.

A commercially available product may be used as the alkyl alcohol poly(alkylene oxide) adduct. As the commercially available product of the alkyl alcohol poly(alkylene oxide) adduct, for example, there may be mentioned, but not limited to, a polyoxyethylene methyl ether (methyl alcohol ethylene oxide adduct) (BLAUNON MP-400, MP-550, or MP-1000) manufactured by Aoki Oil Industrial Co., Ltd., a polyoxyethylene decyl ether (decyl alcohol ethylene oxide adduct) (FINESURF D-1303, D-1305, D-1307, or D-1310) manufactured by Aoki Oil Industrial Co., Ltd., a polyoxyethylene lauryl ether (lauryl alcohol ethylene oxide adduct) (BLAUNON EL 1505) manufactured by Aoki Oil Industrial Co., Ltd., a polyoxyethylene cetyl ether (cetyl alcohol ethylene oxide adduct) (BLAUNON CH-305 or CH-310) manufactured by Aoki Oil industrial Co., Ltd., a polyoxyethylene stearyl ether (stearyl alcohol ethylene oxide adduct) (BLAUNON SR-705, SR-707, SR-715 SR-720, SR-730, or SR-750) manufactured By Aoki Oil Industrial Co., Ltd., a random polymerization type polyoxyethylene polyoxypropylene stearyl ether (BLAUNON SA-50/50 1000R or SA-30/70 2000R) manufactured by Aoki Oil Industrial Co., Ltd., a polyoxyethylene methyl ether (Pluriol A760E) manufactured by BASF, or a polyoxyethylene alkyl ether (Emulgen Series) manufactured by Kao Corp.

The internal addition type mold release agents may be used alone, or at least taro types thereof may be used in combination.

When the internal addition type mold release agent is added to a curable composition, as the internal addition type mold release agent, at least one of a fluorine-based surfactant and a hydrocarbon-based surfactant is preferably added.

When the composition (1) according to this embodiment contains an internal addition type mold release agent as the addition component (C), the content of this internal addition type mold release agent is, with respect to the total of the component (A), preferably 0.001 to 10 percent by weight. In addition, the content is more preferably 0.01 to 7 percent by weight and particularly preferably 0.05 to 5 percent by weight.

When the content of the internal addition type mold release agent is set to 10 percent by weight or less with respect to the total of the component (A), the degradation in curing properties of the composition (1) can be suppressed. That is, for example, even if the composition (1) is cured with a low exposure amount, at least the surface of the cured product is sufficiently cured, and defects of pattern collapse is not likely to occur. In addition, when the content of the internal addition type mold release agent is set to 0.001 percent by weight or more with respect to the total of the component (A), an effect of reducing a mold releasing force and/or an effect of improving filling properties can be obtained.

The composition (1) according to this embodiment is preferably a nanoimprint curable composition and more preferably a photo-nanoimprint curable resin composition.

In addition, by analysis of the composition (1) according to this embodiment or the cured product obtained by curing the composition (1) using an infrared spectroscopic method, an ultraviolet-visible spectroscopic method, a thermal decomposition gas chromatographic mass analysis, or the like, the ratio of the component (A) to the component (B) can be obtained. As a result, the ratio of the component (A) to the component (B) in the composition (1) can be obtained. When the addition component (C) is contained, by a method similar to that described above, the ratio among the component (A), the component (B), and the component (C) can also be obtained.

In addition, although a solvent may also be used for the composition (1) according to this embodiment, it is preferable that a solvent is not substantially contained in the composition (1). The “solvent is not substantially contained” indicates the case in which a solvent other than an unintentionally contained solvent, such as impurities, is not contained. That is, for example, the content of the solvent of the composition (1) according to this embodiment is preferably 3 percent by weight or less with respect to the total of the composition (1) and more preferably 1 percent by weight or less. In addition, the “solvent” described in this case indicates a solvent which is generally used for a curable composition or a photoresist. That is, the type of solvent is not particularly limited as long as capable of dissolving or uniformly dispersing a compound to be used in the present invention and being unreactive therewith.

<Temperature in Blending of Pattern Forming Curable Composition>

When the composition (1) according to this embodiment is prepared, at least the component (A) and the component (B) are mixed and dissolved with each other under predetermined temperature conditions. In particular, this operation is performed in a temperature range of 0° C. to 100° C. When the component (C) is contained, an operation similar to that described above is performed.

<Viscosity of Pattern Forming Curable Composition>

The viscosity of a mixture of the components of the composition (1) according to this embodiment other than the solvent at 23° C. is preferably 1 to 100 mPa s. In addition, the viscosity described above is more preferably 1 to 50 mPa s and further preferably 1 to 20 mPa s.

Since the viscosity of the composition (1) is set to 100 mPa s or less, when the composition (1) is brought into contact with a mold, the time required to fill the composition (1) in concave portions of a fine pattern of the mold cannot be long. That is, by the use of the composition (1) according to this embodiment, a nanoimprint method can be performed at a high productivity. In addition, pattern defects caused by insufficient filling are not likely to occur.

In addition, since the viscosity is set to 1 mPa s or more, when the composition (1) is applied to the substrate, coating irregularities are not likely to occur. Furthermore, when the composition (1) is brought into contact with the mold, the composition (1) is not likely to flow out of an end portion of the mold.

<Surface Tension of Pattern Forming Curable Composition>

The surface tension of the mixture of the components of the composition (1) according to this embodiment other than the solvent at 23° C. is preferably 5 to 70 mN/m. In addition, the surface tension described above is more preferably 7 to 35 mN/m and further preferably 10 to 32 mN/m. In his case, since the surface tension is set to 5 mN/m or more, when the composition (1) is brought into contact with the mold, the time required to fill the composition (1) into the concave portions of the fine pattern of the mold cannot be long.

In addition, since the surface tension is set to 70 mN/m or less, a cured product obtained by curing the composition (1) has a surface smoothness.

(Cured Layer Forming Composition: Composition (2))

In this embodiment, a cured layer forming composition (composition (2)) is a composition containing the following component (D) and component (E). The composition (2) is preferably a curable composition further containing a component (B) besides the component (D) and the component (E) but is not limited thereto as long as being a composition forming a cured layer by stimulation such as light or heat. For example, after the composition (2) in which the component (D) is dissolved or dispersed in the component (E) is applied, when the component (E) is removed out of the composition (2) by heating or the like, a cured layer may also be formed. In addition, the composition (2) may contain a compound having intramolecular reactive functional groups functioning as the component (D) and the component (B).
Component (D): a polymerizable component and/or a polymer component
Component (E): a solvent

Hereinafter, the individual components of the composition (2) will be described in detail.

<Component (D): Polymerizable Component and/or Polymer Component>

The component (D) is a polymerizable component and/or a polymer component. The polymer component according to this embodiment is a polymer which has a structure of repeating units each derived from at least one type of monomer and which has a molecular weight of 1,000 or more.

In this embodiment, as the polymerizable component of the component (D), besides the polymerizable compound which can be used as the component (A) described above, an arbitrary compound to be polymerized by an addition reaction, a substitution reaction, a condensation reaction, a ring-opening reaction, or the like may also be used. That is, the compound contained in the component (D) is not particularly limited as long as capable of forming a cured layer by stimulation, such as light or heat, and/or by evaporation of a solvent (component (E)).

In particular, as a high molecular weight compound obtained by a polymerization reaction of the polymerizable compound contained in the component (D), for example, there may be mentioned a (meth)acrylic acid derivative polymer, such as a poly(meth)acrylate or a poly(meth)acrylamide; a poly(vinyl ether), a poly(ethylene oxide), a polyoxetane, a poly(propylene oxide), a polyoxymethylene, a poly(allyl ether), a polyethylene, a polypropylene, a polystyrene, a polyester, a polycarbonate, a polyurethane, a polyamide, a poly(amide imide), a poly(ether imide), a polyimide, a polysulfone, a poly(ether sulfone), a poly(ether ether ketone), a phenol resin, a melamine resin, or a urea resin. However, the high molecular weight compound is not limited to those mentioned above as long as being formed from the component (D) by stimulation, such as light or heat, and/or by evaporation of the solvent (component (E)).

Those polymerizable compounds may be used alone, or at least two types thereof may be used in combination.

In addition, as the polymer component of the component (D), for example, there may be mentioned, but not limited to, a (meth)acrylic acid derivative polymer, such as a poly(meth)acrylate or a poly(meth)acrylamide; a poly(vinyl ether), a poly(ethylene oxide), a polyoxetane, a poly(propylene oxide), a polyoxymethylene, a poly(allyl ether), a polyethylene, a polypropylene, a polystyrene, a polyester, a polycarbonate, a polyurethane, a polyamide, a poly(amide imide), a poly(ether imide), a polyimide, a polysulfone, a poly(ether sulfone), a poly(ether ether ketone), a phenol resin, a melamine resin, or a urea resin.

Those polymer components may be used alone, or at least two types thereof may be used in combination.

In this embodiment, when the composition (2) is an adhesion layer forming composition, a compound having intramolecular reactive functional groups which are to be bonded to two layers (such as a base material and the composition (1) functioning as a curable composition) is preferably contained as the component (D).

<Component (B): Polymerization Initiator>

As is the composition (1), the composition (2) according to this embodiment may also contain a polymerization initiator as the component (B).

As is the composition (1), the blending rate of the component (B) as the polymerization initiator in the composition (2) with respect to the total of the component (D) is preferably 0.01 to 10 percent by weight and more preferably 0.1 to 7 percent by weight.

When the blending rate of the component (B) with respect to the total of the component (D) is set to 0.01 percent by weight or more, the curing rate of the composition (2) can be increased. As a result, the reaction efficiently can be improved. In addition, when the blending rate of the component (B) with respect to the total of the component (D) is set to 10 percent by weight or less, a cured product to be obtained may have a certain mechanical strength.

However, when the polymer component is only used as the component (D), since the polymerization is not longer required to be started, the blending rate of the component (B) with respect to the total of the component (D) is preferably set to less than 0.01 percent by weight.

<Component (E): Solvent>

The component (E) is a solvent. The component (E) according to this embodiment is not particularly limited as long as being a solvent dissolving the component (D) or the component (D) and the component (B). As a preferable solvent, a solvent having a boiling point of 80° C. to 200° C. at a normal pressure may be mentioned. A solvent having at least one of a hydroxyl group, an ether structure, an ester structure, and a ketone structure is further preferable. Those solvents are preferable since excellent in dissolving the component (D) and the component (B) and excellent in wetting the base material.

As the component (E) according to this embodiment, for example, an alcohol solvent, such as propyl alcohol, isopropyl alcohol, or butyl alcohol; an ether solvent, such as ethylene glycol monomethyl ether, ethylene glycol dimethyl ether, ethylene glycol monoethyl ether, ethylene glycol diethyl ether, ethylene glycol monobutyl ether, or propylene glycol monomethyl ether; an ester solvent, such as butyl acetate, ethylene glycol monoethyl ether acetate, ethylene glycol monobutyl ether acetate, or propylene glycol monomethyl ether acetate; or a ketone solvent, such as methyl isobutyl ketone, diisobutyl ketone, cyclohexanone, 2-hepatnone, γ-butyrolactone, or ethyl lactate, may be used alone or in combination. Among those mentioned above, propylene glycol monomethyl ether acetate or a mixed solvent thereof is preferable in view of coatability.

Although the blending rate of the component (E) according to this embodiment to the composition (2) can be appropriately adjusted by the viscosity and the coatability of each of the component (D) and the component (B) and the thickness of a cured layer to be formed, the blending rate is preferably 70 percent by weight or more with respect to the total of the composition (2). The blending rate is more preferably 90 percent by weight or more and more preferably 95 percent by weight or more. Since the thickness of the cured layer to be formed can be decreased as the amount of the solvent (E) is increased, when the composition (2) is used as a nanoimprint adhesion layer forming composition or the like, a higher blending rate is particularly preferable. In addition, when the blending rate of the component (E) to the composition (2) is 70 percent by weight or less, a sufficient coatability may not be obtained in some cases.

<Other Addition Components (F)>

Besides the component (D), the component (E), and the component (B), in accordance with various purposes, the composition (2) according to this embodiment may further contain at least one addition component (F) without degrading the advantage of the present invention. As the addition component described above, for example, a sensitizer, a hydrogen donor, a surfactant, a cross-linking agent, an antioxidant, or a polymerization inhibitor may be mentioned.

<Viscosity of Cured Layer Forming Composition>

Although varied depending on the types of component (D), component (E), and component (B) and the blending rates thereof, the viscosity of the composition (2) according to this embodiment at 23° C. is preferably 0.5 to 20 mPa s. The viscosity described above is more preferably 1 to 10 mPa s and further preferably 1 to 5 mPa s. Since the viscosity of the composition (2) is set to 20 mPa s or less, excellent coatability is obtained, and the thickness of the cured layer can be easily adjusted.

### Impurities Mixed in Nanoimprint Liquid Material

In the liquid material L according to this embodiment, the content of impurities is preferably decreased as much as possible. The “impurities” described here indicates materials other than those which are intentionally contained in the liquid material L. That is, when the liquid material L is the composition (1), the impurities are materials other than the component (A), the component (B), and the addition component (C), and when the liquid material L is the composition (2), the impurities are materials other than the component (I)), the component (E), the component (B), and the addition component (F). In particular, for example, particles, metal impurities, and organic impurities may be mentioned, but the impurities are not limited to those mentioned above,

<Particles>

The particles according to this embodiment indicate minute foreign particles. The particles each typically indicate a gel or a solid particulate substance having a particle diameter of several nanometers to several micrometers or an air bubble (hereinafter simply referred to as “nanobubble”) such as a nanobubble or a microbubble.

When a photo-nanoimprint process is performed using a liquid material L containing particles, troubles, such as damage to the mold and/or pattern defects after molding, may disadvantageously occur. For example, when particles are present in the composition (1) applied on the substrate in the arrangement step of the photo-nanoimprint process, in the subsequent mold contact step [2] and alignment step [3] which will be described later, damage may be done to the mold in some cases. For example, since particles are blocked in concave portions of the concave-convex pattern formed in the surface of the mold, or the width of the concave portion is increased by a particle, the concave-convex pattern may be destroyed in sonic cases. In concomitance with this trouble, pattern defects are generated, and hence, a problem in that a desired circuit is not formed may arise in some cases.

In addition, when particles are present in the composition (2), particles having a large particle diameter as compared to the thickness of the cured layer may have adverse influences on the nanoimprint process and/or a product to be obtained thereby. For example, in the mold contact step [2] and the alignment step [3], damage may be done to the mold in some cases.

In addition, when nanobubbles are present in the composition (1) or the composition (2), the curing properties of the composition (1) or the composition (2) may be degraded in some cases. The reason for this is believed that oxygen and the like in the nanobubble inhibits a polymerization reaction of the composition (1) or the coin-position (2). In addition, when nanobubbles are present in the composition (1), a concave-convex pattern in which a portion at which the nanobubble is present is lacked may be disadvantageously formed in sonic cases.

Hence, a lower particle number concentration (/mL) of particles contained in the liquid material L is more preferable. Furthermore, a smaller particle diameter of the particles contained in the liquid material L is more preferable.

(Particle Number Concentration of Particles)

As described above, when many particles having a certain particle diameter or more are contained in the liquid material L, the nanoimprint process may be adversely influenced thereby in some cases. In particular, when the nanoimprint process is repeatedly performed on different regions on the substrate as described below, if damage is done to the mold during the process, every subsequent transferred pattern has a defect. As a result, the yield is seriously decreased.

In order to suppress the decrease in yield as described above, the number of particles contained in a volume of the liquid material L necessary to process one substrate (wafer) may be set to less than one.

As one example of this embodiment, the case is assumed in which by the use of a mold (width: 26 mm, length: 33 mm) with a 28-nm L/S (line/space) pattern, a cured product having an average film thickness of 40.1 nm is formed by a nanoimprint process.

In this case, 35.1 nL of the liquid material L is required for one shot (repeating unit including steps [1] to [5] which are to be described below). For example, when a wafer having a size of 300 mm is used, 92 shots can be performed on one wafer. That is, 3,229.2 nL, of the liquid material L is required for one wafer. Hence, 310 wafers each having a size of 300 ram can be processed by 1 mL of the liquid material L.

Hence, when the nanoimprint process is performed using a wafer having a size of 300 mm, the particle number concentration (/mL) of particles contained in the liquid material L is preferably set to less than 310/mL. Accordingly, the number of particles per one wafer having a size of 300 mm can be set to less than one, and hence the yield of the nanoimprint process can be improved.

As is the case described above, when the photo-nanoimprint process is performed using a wafer having a size of 450 mm, the particle number concentration (/mL) of particles contained in the liquid material L is preferably set to less than 137/mL. Incidentally, when a wafer having a size of 450 mm is used, since 208 shots can he performed per one wafer, the calculation is performed based on this number of shots.

(Size of Particles)

When the distance between front ends of convex portions of the concave-convex pattern formed in the surface of the mold is increased by some sort of force applied to the pattern, and the front end is brought into contact with a front end adjacent thereto, damage is liable to be done to the mold. Hereinafter, the influence of the particles contained in the liquid material L is considered.

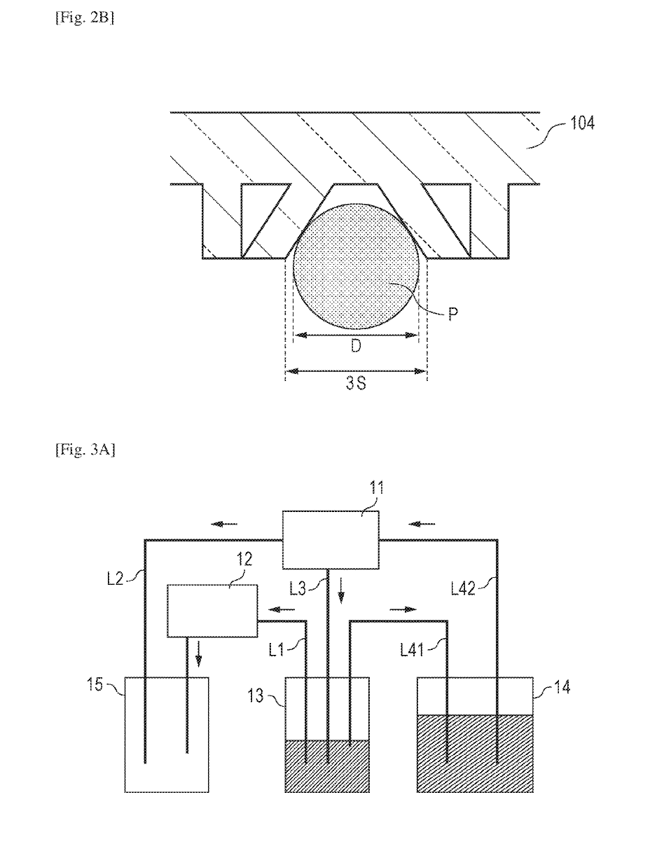

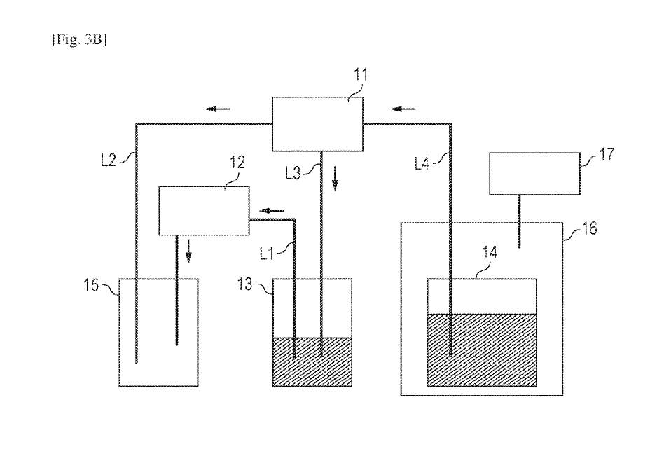

FIGS. 2A and 2B are each a schematic cross-sectional view showing a concave-convex pattern formed in the surface of a mold. FIG. 2A shows a mold having an L/S pattern in which the width of the concave portion of the mold is S (nm), and the width of the convex portion is L (nm).

As shown in FIG. 2B, when the distance between the convex portions formed in the surface of the mold is increased, and each convex portion is brought into contact with a convex portion adjacent thereto, the distance between the convex portions thus increased becomes 3S (nm). Hence, when the diameter D (nm) of the particle is approximately larger than 3S (nm) (D>3S) as shown in FIG. 2B, it can be supposed that the mold is damaged.

Accordingly, for example, even if only one, particle having a diameter of 0.07 μm or more is present on the wafer, when a mold having an L/S pattern in which S is less than 23.3 nm is used, damage may be done to the mold in some cases.

In addition, since deformability of the mold is actually varied depending on the material of the mold, the shape of the concave-convex pattern, the aspect ratio (H/L) of the concave-convex pattern, and the like, damage is not always done to the mold when D>3S is strictly satisfied, and the ratio of D to S has a predetermined allowable range. That is, even if the ratio of D to S (D/S) is 3 or less, damage may be done to the mold in some cases. Hence, in the liquid material L according to this embodiment, the particle number concentration of particles having a particle diameter of 2.5S (nm) is preferably less than 310/mL.

In addition, the width S (nm) of the concave portion of the concave-convex pattern formed in the surface of the mold is preferably 4 to less than 30 nm and more preferably 10 to less than 23.3 nm. Furthermore, in particular, in the case of semi-conductor manufacturing application, a mold having an aspect ratio (HIS) of 1 to 10 is preferably used.

According to those described above, as for the particle number concentration (/mL) of particles contained in the liquid material L, when the width of the concave portion of the concave-convex pattern of the mold is S (nm), the particle number concentration of particles having a particle diameter of 2.5S (nm) or more is preferably less than 310/mL. As a result, the yield of the nanoimprint process can be improved.

in addition, the particle number concentration (/mL) of particles having a particle diameter of 0.07 μM or more is more preferably less than 310/mL. Accordingly, when the nanoimprint process is performed using a wafer having a size of 300 mm, the yield of the nanoimprint process can be improved. Furthermore, as for the particle number concentration (/mL) of particles contained in the liquid material L, the particle number concentration (/mL) of particles having a particle diameter of 0.07 μm or more is even more preferably less than 137/mL. Accordingly, when the nanoimprint process is performed using a wafer having a size of 450 mm, the yield of the nanoimprint process can be improved.

<Metal Impurities>

When a semiconductor device is manufactured using the liquid material L according to this embodiment, if metal impurities are present in the liquid material L, a substrate to be processed is contaminated by the metal impurities when the liquid material L is applied thereon. As a result, the semiconductor properties of a semiconductor device to be obtained may be adversely influenced thereby in some cases. That is, the yield of the nanoimprint process may be decreased in some cases.

Hence, the concentration of the metal impurities in the liquid material L is preferably decreased. As the concentration of the metal impurities contained in the liquid material L, the contents of various types of elements are each preferably 100 ppb (100 ng/g) or less and are each more preferably set to 1 ppb (1 ng/g) or less. The various types of elements described above indicate metal elements, such as Na, Ca, Fe, K, Zn, Al, Mg, Ni, Cr, Cu, Pb, Mn, Li, Sn, Pd, Ba, Co, and Sr. When the concentrations of those elements in the liquid material L are each set in the range described above, the influence of the liquid material L on the semiconductor properties of the semi-conductor device can be reduced. That is, the yield of the nanoimprint process can be suppressed from being decreased.

### <Organic Impurities>

When a semiconductor device is manufactured using the liquid material L according to this embodiment, if organic impurities are present in the liquid material L, defects may be generated in some cases. For example, when the organic impurities are present in the composition (I), for example, defects may be generated in a pattern obtained after molding.

Measurement of Particle Number Concentration of Particles Contained in Nanoimprint Liquid Material

The particle number concentration (/mL) of particles contained in the liquid material

L and the particle diameter distribution thereof can be measured by a method using a light scattering liquid-borne particle counter (light scattering LPC) or a dynamic light scattering particle diameter distribution measurement apparatus (DLS). As is the case of this embodiment, for a liquid material having a small particle number concentration of particles (/mL), that is, for a liquid material having a high degree of cleanness, a light scattering LPC is preferably used for the measurement of the particle number concentration of particles.

When a liquid is irradiated by laser light, the light scattering LPC detects scattering light emitted from particles contained in the liquid. In this case, the intensity of this scattering light is dependent on the size of the particle. By the use of this relationship, the light scattering LPC can measure the particle diameter and the particle number concentration of particles in the liquid.

As a concrete example of the light scattering LPC, for example, a liquid-borne particle sensor KS series (manufactured by Rion Co., Ltd.), and a liquid-borne particle counter UltraChem series, SLS series, and HSLIS series (manufactured by Particle Measuring Systems) may be mentioned. Since a measurable liquid composition and a measurable minimum particle diameter are varied depending on the type of liquid-borne particle counter to be used for measurement, the type of counter is required to be appropriately selected in accordance with the liquid to be measured. For example, in the case of the composition (1) which is a photocurable composition or the like, it has been known that since the background noise by molecular scattering light is large, the S/N ratio of detected signal is decreased. Hence, compared to an aqueous-based material, the measurement of the particle number concentration of particles and the particle diameter distribution of the liquid material L according to this embodiment cannot be easily performed. Hence, in this embodiment, for the measurement of the liquid material L, an apparatus capable of measuring the particle number concentration of particles having a small particle diameter, such as 0.07 μm, is preferably used.

The liquid material L according to this embodiment is characterized in that the particle number concentration of particles having a particle diameter of 0.07 μm or more is less than 310/mL. In addition, the particle number concentration (/mL) of particles having a particle diameter of 0.07 μm or more contained in the liquid material L according to this embodiment can be measured by, for example, a liquid-borne particle sensor KS-41B (with an option for a particle size of 0.07 μm) (manufactured by Rion Co., Ltd.). In addition, in this measurement, a controller KE-40B1 (manufactured by Rion Co., Ltd.) and a syringe sampler KZ-30W1 (manufactured by Rion Co., Ltd.) are also preferably used together.

In addition, every measurement of the particle number concentration of particles in this specification is preferably performed after the light scattering LPC is calibrated using polystyrene latex (PSL) standard particles which have a predetermined particle diameter and which are dispersed in purified water. In addition, immediately after the measurement, it is preferably confirmed using a pulse height-analysis software KF-50A (manufactured by Rion Co., Ltd.) that the accuracy of the measurement value of the particle number concentration of particles having a particle diameter of 0.07 μm or more is sufficiently ensured. In particular, it is preferably confirmed that the ratio (s/n) of a light receiving-element voltage s of scattering light of a 0.07-μm PSL particle aqueous solution to a light receiving-element voltage n of scattering light of a measurement liquid is sufficiently larger than 1.3.

Method for Manufacturing Nanoimprint Liquid Material

Next, a method for manufacturing the liquid material L according to this embodiment will be described.

A method for manufacturing a nanoimprint liquid material according to this embodiment includes a purification step of purifying a nanoimprint liquid material by filtration using a filter, and the refining step includes [a] a step of filtrating a crude nanoimprint, liquid material at a flow rate of less than 0.03 L./min using a filter having a pore diameter of 50 nm or less, and a step of recovering a flow fraction other than an initial flow fraction of the crude nanoimprint liquid material passing through the filter in a container connected to a particle number concentration measurement system.

A liquid material L obtained by the method for manufacturing the liquid material L according to this embodiment is suitable for a photo-nanoimprint process and more suitable for a photo-nanoimprint process in semiconductor manufacturing application.

As described above, in the liquid material L according to this embodiment, the content of impurities, such as particles and metal impurities, is preferably decreased as much as possible. Hence, the liquid material L according to this embodiment is preferably obtained through a purification step. As the purification step described above, for example, a particle removing step, a metal impurity removing step, and an organic impurity removing step may be mentioned. Among those mentioned above, in order to suppress the damage done to the mold, the method for manufacturing the liquid material L preferably includes the particle removing step.

As the particle removing step according to this embodiment, for example, filtration using a particle filter (hereinafter simply referred to as “filter”) is preferable. In addition, besides the “filtration” which is used in general to indicate a step of separating a solid from a fluid, the “filtration” in this specification includes the case in which “a fluid is simply allowed to pass through a filter”. That is, for example, the filtration also includes the case in which even when a fluid is allowed to pass through a membrane, such as a filter, a gel or a solid trapped by the membrane is not visually confirmed.

The pore diameter of the filter to be used in the particle removing step according to this embodiment is preferably 0.001 to 5.0 μm. In addition, in order to decrease the particle number concentration (/mL) of particles having a particle diameter of 0.07 μm or more, a filter having a pore diameter of 50 nm or less is more preferable, and a filter having a pore diameter of 1 to 5 nm is particularly preferable. In addition, when filtration is performed using a filter having a pore diameter of less than 1 mm a component necessary in the liquid material L may be removed in some cases, and hence, the pore diameter of the filter is preferably 1 nm or more. In addition, the “pore diameter” of the filter in this case is preferably the average pore diameter of pores of the filter.

When the filtration is performed using a filter, a crude nanoimprint liquid material (hereinafter referred to as “crude liquid material L”) is allowed to pass at least once through the filter. In addition, the crude liquid material L indicates a liquid material which is not processed by the purification step, such as filtration. In particular, when the liquid material L is the composition (1), the crude liquid material L is a mixed liquid obtained by mixing the component (A), the component (B), and the component (C) which is added if needed. In addition, when the liquid material L is the composition (2), the crude liquid material L is a mixed liquid obtained by mixing the component (D), the component (E), the component (F), and the component (B), the latter two components of which are added if needed.

As the filter used for the filtration, a filter formed of a polyethylene resin, a polypropylene resin, a fluorinated resin, a nylon resin, or the like may be used but not limited thereto. As concrete examples of the filter usable in this embodiment, for example, there may be used “Ultipleat P-Nylon 66”, “Ultipore N66”, and “Penflon” (manufactured by Nihon Pall Ltd.); “LifeASSURE PSN series”, “LifeASSURE EF series”, “PhotoSHIELD”, and “Electropore HEE” (manufactured by Sumitomo 3M Limited.); and “Microguard”, “Optimizer D”, “Impact Mini”, and “Impact 2” (manufactured by Nihon Entegris K.K.). Those filters mentioned above may be used alone, or at least two types thereof may be used in combination.

In addition, it is preferable that the filtration using a filter is performed in a multistage manner or is repeatedly performed many times. In this case, a cycle filtration in which a liquid obtained by filtration is repeatedly filtrated may be performed. In addition, filtration may be performed using a plurality of filters having different pore diameters. As a filtration method using a filter, in particular, although a normal pressure filtration, a pressure filtration, a reduced-pressure filtration, a cycle filtration, or the like may be mentioned but not limited thereto. Among those mentioned above, in order to decrease the particle number concentration (/mL) of particles by filtrating the liquid material L at a flow rate in a predetermined range, a pressure filtration is preferably performed, and in order to further sufficiently decrease the particle number concentration of particles, a cycle filtration is more preferably performed.

In addition, when a pressure filtration is performed, the final flow fraction which is a flow fraction obtained when the amount of the raw material before filtration (crude liquid material L) is decreased to a predetermined volume or less is preferably not recovered. When the amount of the raw material before filtration is decreased to a predetermined volume or less, the raw material may be probably transported while incorporating surrounding air during a liquid transport step, and as a result, many bubbles, such as nanobubbles, may be incorporated in some cases. Hence, when a pressure filtration is performed instead of a cycle filtration, a flow fraction other than the initial flow fraction and the final flow fraction is preferably recovered in a recovery container.

FIGS. 3A and 3B are schematic views each showing the structure of a purification system of the liquid material L according to this embodiment. FIG. 3A shows the structure of a purification system by a cycle filtration, and FIG. 3B shows the structure of a purification system by a pressure filtration.

The purification system by a cycle filtration according to this embodiment includes, as shown in FIG. 3A, a purification device 11, a particle number concentration measurement system 12 (hereinafter referred to as “measurement system 12”), a recovery container 13, a buffer container 14, and a waste liquid container 15. In addition, the purification system by a pressure filtration includes, as shown in FIG. 3B, a purification device 11, a measurement system 12, a recovery container 13, a container 14, a waste liquid container 15, and a pressure system 17.

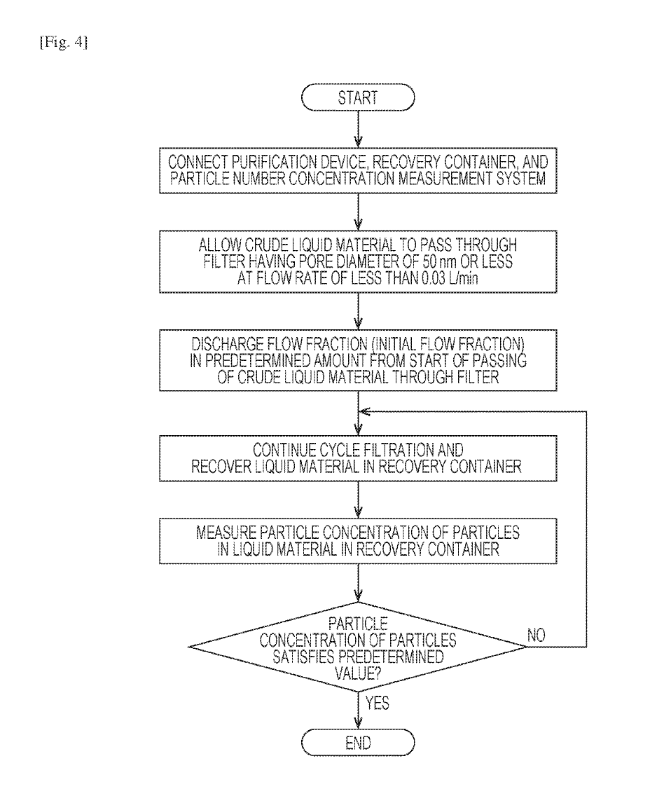

Next, as one example of the method for manufacturing the liquid material L according to this embodiment, a method for manufacturing the liquid material L using the purification system shown in FIG. 3A will be described with reference to FIG. 4.

First, the crude liquid material L which is a raw material is received in the buffer container 14, and the purification device 11 is driven. The purification device 11 has a liquid transport unit (not shown) and a filter (not shown). In addition, in this step, a flow path of a pipe L42 and a flow path of a pipe L3 are not communicated with each other, and the flow path of the pipe L42 and a flow path of a pipe L2 are communicated with each other. By driving the purification device 11, the liquid transport unit (not shown) is driven, and the crude liquid material L is transported to the purification device 11 through the pipe L42. Subsequently, the crude liquid material L is allowed to pass through the filter (not shown) of the purification device 11. The crude liquid material L allowed to pass through the filter is transported to the waste liquid container 15.

In this step, the flow rate of the crude liquid material L is preferably less than 0.03 L/min. In addition, the flow rate is more preferably less than 0.02 L/min and particularly preferably less than 0.01 L/min. As described above, when the flow rate of the crude liquid material L passing through the filter during the filtration is set to less than 0.03 L/min, bubbles can be suppressed from being generated when the crude liquid material L is allowed to pass through the filter. When the flow rate of the crude liquid material L passing through the filter during filtration is set to less than 0.01 L/min, the probability of flashing of the crude liquid material L can be reduced.

In addition, the pore diameter of the filter which allows the crude liquid material L to pass therethrough in this embodiment is set to 50 nm or less. Accordingly, the particle number concentration (/mL) of particles having a particle diameter of 0.07 μm or more can be effectively decreased.

In addition, in the purification system of the liquid material L according to this embodiment, as members with which the (crude) liquid material L is brought into contact, for example, the inside walls and the lids of the recovery container 13 and the buffer container 14, the inside walls of the pipes (tubes), nuts connecting the pipes, the pump (liquid transport unit), and the filter may be mentioned. The materials of those members are not particularly limited as long as having a chemical resistance. However, those members are preferably formed of materials having quality and degree of cleanness so as not to cause contamination by impurities, such as particles, metal impurities, organic impurities, and the like when being brought into contact with the (crude) liquid material L.

Among the members described above, for the recovery container 13 in which the liquid material L refined by the purification system according to this embodiment is recovered, in particular, a material having a high degree of cleanness is necessarily used. As the recovery container 13, for example, a commercially available class 100 polypropylene bottle may be used. However, the material is not limited thereto, and a bottle prepared in such a way that after the inside thereof is washed with an organic solvent and/or an acid, drying is sufficiently performed may be used, or the bottle described above may also be used after being washed with the liquid material L which is to be processed.

Next, the “initial flow fraction” which is flow fraction in a predetermined amount obtained from the start of passing of the crude liquid material L through the filter is transported to the waste liquid container 15. That is, in this embodiment, the initial flow fraction is not recovered in the recovery container 13. When the crude liquid material L is allowed to pass through the filter, the pressure loss is generated. In concomitance with this phenomenon, bubbles may be generated in the liquid material L in some cases. In the initial flow fraction obtained from the start of passing of the crude liquid material L through the filter, the generation of the bubbles is particularly remarkable.

Accordingly, this initial flow fraction is removed in this embodiment, and the flow fraction other than the initial flow fraction is recovered in the recovery container 13. Hence, new impurities, such as bubbles, can be suppressed from being mixed into the liquid material L.

In particular, after the insides of the pipe L42 and the purification device 11 are purged by the crude liquid material L, the flow path of the pipe L42 and the flow path of the pipe L3 are communicated with each other. In this step, the front end (end portion inserted into the container 14 in FIG. 3A) of a pipe L41 is inserted into the waste liquid container 15 in advance. Accordingly, the crude liquid material L transported to the recovery container 13 through the pipe L3 is further transported by drive of the liquid transport unit (not shown) to the waste liquid container 15 through the pipe L41. The step described above is continuously performed until a predetermined amount of the crude liquid material L is allowed to pass through the filter, so that a predetermined amount of the initial flow fraction can be removed.

Subsequently, as shown in FIG. 3A, the front end of the pipe L41 is inserted into the container 14 instead of being inserted into the waste liquid container 15. Accordingly, the flow fraction (targeted flow fraction) other than the initial flow fraction is processed by a cycle filtration and is recovered in the recovery container 13.

In the purification system of the liquid material L according to this embodiment, the recovery container 13 recovering the targeted flow fraction (liquid material L after the purification) is preferably in-line arranged in the line of the purification system. By the arrangement as described above, new impurities, such as nanobubbles, can be suppressed from being generated in the liquid material L.

The cycle filtration is performed a predetermined number of times or is performed for a predetermined amount, so that the liquid material L processed by the purification is obtained. Subsequently, by the use of the measurement system 12 connected to the recovery container 13, the particle number concentration of particles is measured. When the particle number concentration of particles satisfies a predetermined value, the filtration is stopped, and when the predetermined value is not satisfied, the filtration may be further continued.

As described above, in the method for manufacturing the liquid material L according to this embodiment, during or after the filtration of the crude liquid material L, a connection change operation is not performed on the recovery container 13. In more particular, while the recovery container 13 and the measurement system 12 are connected to each other, the cycle filtration is performed. As described above, nanobubbles generated in concomitance with the connection change operation of the pipes and impurities derived from the members caused by friction/abrasion thereof can be suppressed from being generated. Accordingly, the measurement of the particle number concentration (/mL) of particles can be more accurately performed.

Since the purification step (particle removing step) as described above is performed, the number of impurities, such as particles, mixed in the liquid material L can be decreased. Accordingly, the decrease in yield of the nanoimprint process caused by particles can be suppressed.

In addition, when the liquid material L according to this embodiment is used to manufacture a semiconductor integrated circuit, in order not to disturb the performance of the product, impurities (metal impurities) containing metal atoms are preferably suppressed from being mixed in the liquid material as much as possible.

Hence, the liquid material L is preferably not to be brought into contact with metals in the manufacturing process. That is, when the materials are weighed and/or blended together followed by mixing, metal-made weight measuring devices, containers, and the like are preferably not to be used. In addition, in the purification step (particle removing step) described above, filtration using a metal impurity removing filter may be further performed.

As the metal impurity removing filter, a filter made of a cellulose, a diatomite, an ion exchange resin, or the like may be used but is not particularly limited thereto. As the metal impurity removing filter, for example, there may be used “Zeta Plus GN Grade” and “Electropore” (manufactured by Sumitomo 3M Limited.); “Posidyne”, “Ion Clean AN”, and “Ion Clean SL” (manufactured by Nihon Pall Ltd.); and “Purotego” (manufactured by Nihon Entegris K.K.). Those metal impurity removing filters may be used alone, or at least two types thereof may be used in combination.

Those metal impurity removing filters are preferably used after being cleaned. As a cleaning method, washing with ultra-purified water, washing with an alcohol, and washing with the curable composition which is to be processed are preferably performed in this order.

As the pore diameter of the metal impurity removing filter, for example, a pore diameter of 0.001 to 5.0 nm is suitable, and a pore diameter of 0.003 to 0.01 μm is preferable. When the pore diameter is more than 5.0 μm, the adsorption ability to particles and metal impurities is low. In addition, when the pore diameter is smaller than 0.001 μm, since constituent components of the liquid material L are also trapped, the composition of the liquid material L may be varied in some cases, and/or the filter may be blocked in some cases.

In the case as described above, the concentration of metal impurities contained in the liquid material L is preferably decreased to 10 ppm or less and more preferably to 100 ppb or less.

### Cured Film

When the liquid material L according to this embodiment is cured, a cured product is obtained. In this case, a cured film is preferably obtained in such a way that after the liquid material L is applied onto the base material to form a coating film, curing thereof is performed. A method for forming a coating film and a method for forming a cured product or a cured film will be described later.

Method for Manufacturing Cured product Pattern

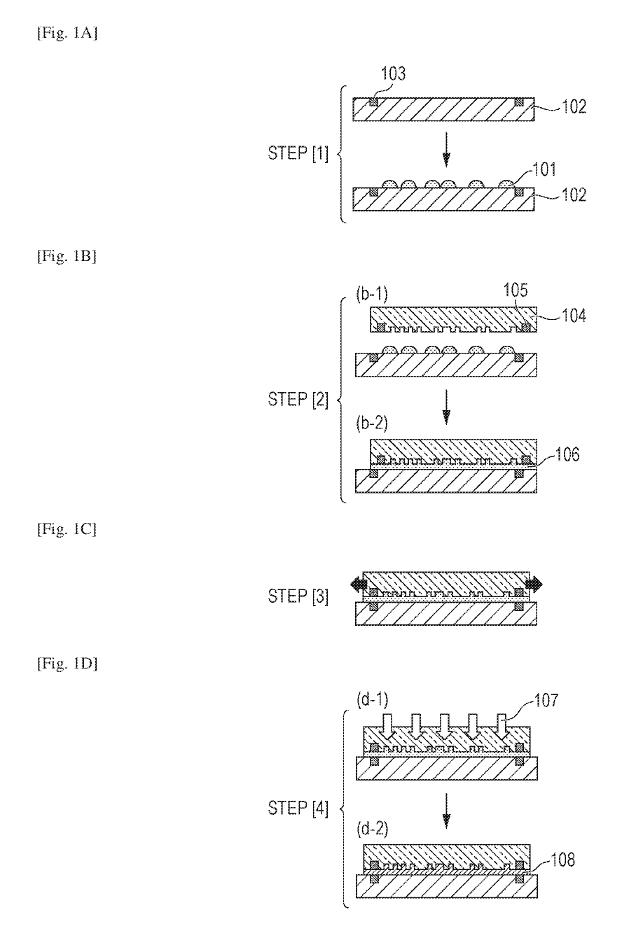

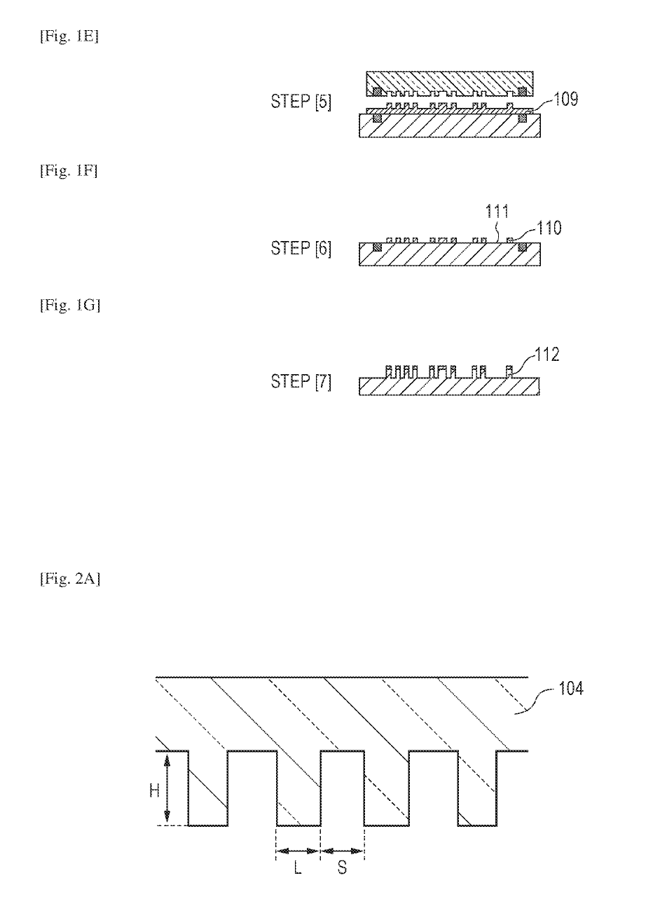

Next, a method for manufacturing a cured product pattern will be described in which a cured product pattern is formed using a photocurable composition as the composition (1) according to this embodiment. FIGS. 1A to 1G are cross-sectional views schematically showing one example of a method for manufacturing a cured product pattern according to this embodiment.

The method for manufacturing a cured product pattern according to this embodiment includes;

[1] a first step (arrangement step) of arranging the above photocurable composition according to this embodiment on a substrate;

[2] a second step (mold contact step) of bringing the photocurable composition into contact with a mold;

[4] a third step (light irradiation step) of irradiating the photocurable composition with light; and

[5] a fourth step (mold release step) of releasing the cured product obtained in the step [4] from the mold.

The method for manufacturing a cured product pattern according to this embodiment is a method for manufacturing a cured product pattern using a photo-nanoimprint method.

A cured film obtained by the method for manufacturing a cured product pattern according to this embodiment is preferably a cured product pattern having a pattern size of 1 nm to 10 mm. In addition, the cured film is more preferably a cured product pattern having a pattern size of 10 nm to 100 μm. In particular, in the case of semi-conductor manufacturing application, the cured film is particularly preferably a cured product pattern having a pattern size of 4 to less than 30 nm.

Hereinafter, the individual steps will be described.

<Arrangement Step [1]>

In this step (arrangement step), as shown in FIG. 1A, a photocurable composition 101, which is one type of liquid material L according to this embodiment, is arranged. (applied) on a substrate 102 to form a coating film.

The substrate 102 on which the photocurable composition 101 is to be arranged is a substrate to be processed, and a silicon wafer is generally used.

However, in this embodiment, the substrate 102 is not limited to a silicon wafer. The substrate 102 may be arbitrarily selected from known semiconductor device-purpose substrates formed of aluminum, a titanium-tungsten alloy, an aluminum-silicon alloy, an aluminum-copper-silicon alloy, a silicon oxide, and a silicon nitride. In addition, as the substrate 102 (substrate to be processed) to be used, there may be used a substrate having an improved adhesion to the photocurable composition 101 by a surface treatment, such as a silane coupling treatment, a silazane treatment, or a film formation of an organic thin film.

In this embodiment, as a method for arranging the photocurable composition 101 on the substrate 102, for example, there may be used an inkjet method, a dip coating method, an air-knife coating method, a curtain coating method, a wire-bar coating method, a gravure coating method, an extrusion coating method, a spin coating method, or a slit scanning method. In the photo-nanoimprint method, in particular, an inkjet method is preferably used. In addition, although the thickness of a layer (coating film) to which the pattern is to be transferred is varied depending on the use application thereof, for example, the thickness is 0.01 to 100.0 μm.

<Mold Contact Step [2]>

Next, as shown in FIG. 1B, a mold 104 having an original pattern to transfer a pattern shape to the coating film is brought into contact with the coating film formed from the photocurable composition 101 in the previous step (arrangement step) ((b-1) of FIG. 1B). Accordingly, (part of) the coating film formed of the photocurable composition 101 is filled in concave portions of the fine pattern of the surface of the mold 104, so that a coating film 106 filled in the fine pattern of the mold is formed ((b-2) of FIG. 1B).

As the mold 104, in consideration of the following step (light irradiation step), a mold 104 formed from a light-transmitting material may be used. As a material forming the mold 104, in particular, for example, glass, quartz, an optical transparent resin, such as a PMMA or a polycarbonate, a transparent metal deposition film, a soft film of a poly(dimethyl siloxane) or the like, a photocurable film, or a metal film may be mentioned. However, when an optical transparent resin is used as the material forming the mold 104, a resin which is not dissolved in components contained in the photocurable composition 101 must be selected. Since having a low coefficient of thermal expansion and a low pattern strain, quartz is particularly preferable as the material forming the mold 104.

The fine pattern of the surface of the mold 104 preferably has a pattern height of 4 to 200 nm and an aspect ratio of 1 to 10.

In order to improve the releasing properties between the photocurable composition 101 and the surface of the mold 104, before this step, which is the mold contact step between the photocurable composition 101 and the mold 104, a surface treatment may be performed on the mold 104. As a method for performing the surface treatment, for example, a method in which a mold release agent is applied on the surface of the mold 104 to form a mold release agent layer may be mentioned. In this case, as the mold release agent to be applied on the surface of the mold 104, for example, there may be mentioned a silicon-based mold release agent, a fluorine-based mold release agent, a hydrocarbon-based mold release agent, a polyethylene-based mold release agent, a polypropylene-based mold release agent, a paraffin-based mold release agent, a montan-based mold release agent, or a carnauba-based mold release agent. For example, a commercially available coating type mold release agent, such as Optool DSX manufactured by Daikin Industries, Ltd., may be preferably used. In addition, the mold release agents may be used alone, or at least two types thereof may be used in combination. Among those mentioned above, a fluorine-based and a hydrocarbon-based mold release agent are particularly preferable.

In this step (mold contact step), as shown in (b-1) of FIG. 1B, when the mold 104 is brought into contact with the photocurable composition 101, the pressure to be applied thereto is not particularly limited. The pressure may be set to 0 to 100 MPa or less. In addition, the pressure is preferably 0 to 50 MPa, more preferably 0 to 30 MPa, and further preferably 0 to 20 MPa.

In addition, in this step, the time required to bring the mold 104 into contact with the photocurable composition 101 is not particularly limited. The time may be set to 0.1 to 600 seconds. In addition, the time is preferably 0.1 to 300 seconds, more preferably 0.1 to 180 seconds, and particularly preferably 0.1 to 120 seconds.

In this step, by the use of a photocurable composition in which the particle number concentration of particles having a particle diameter of 0.07 μm or more is less than 310/mL and which is one type of liquid material L according to this embodiment, damage done to the mold caused by particles can be suppressed. In addition, pattern defects of a cured product pattern to be obtained can be reduced. As a result, the decrease in yield of the nanoimprint process can be suppressed.

Although this step may be performed under any condition selected from an air atmosphere, a reduced-pressure atmosphere, and an inert gas atmosphere, since the influence of oxygen and/or moisture on a curing reaction can be prevented, a reduced-pressure atmosphere or an inert gas atmosphere is preferable. When this step is performed in an inert gas atmosphere, as particular examples of an inert gas which can be used, for example, nitrogen, carbon dioxide, helium, argon, various types of Freon gases, or a mixed gas therebetween may be mentioned. When this step is performed in a specific gas atmosphere including an air atmosphere, a preferable pressure is 0.0001 to 10 atoms.

The mold contact step may be performed in an atmosphere containing a condensable gas (hereinafter referred to as “condensable gas atmosphere”). The condensable gas in this specification indicates a gas which is liquefied by condensation with a capillary force generated when a gas in an atmosphere is filled together with (pall of) the coating film 106 in the concave portion of the fine pattern formed in the mold 104 and in a space formed between the mold and the substrate. In addition, the condensable gas is present in the form of gas in an atmosphere before the photocurable composition 101 (layer to which the pattern is to be transferred) is brought into contact with the mold 104 ((b-1) of FIG. 1B) in the mold contact step.

When the mold contact step is performed in a condensable gas atmosphere, bubbles disappear since the gas filled in the concave portion of the fine pattern is liquefied, and hence the filing properties are excellent. The condensable gas may also be dissolved in the photocurable composition 101.

Although the boiling point of the condensable gas is not particularly limited as long as equivalent to or lower than an atmosphere temperature of the mold contact step, the boiling point is preferably −10° C. to 2.3° C. and further preferably 10° C. to 23° C. When the boiling point is in this range, the filling properties can be further improved.

Although the vapor pressure of the condensable gas at an atmosphere temperature of the mold contact step is not particularly limited as long as equivalent to or lower than a molding pressure to be applied in the mold contact step, the vapor pressure is preferably 0.1 to 0.4 MPa. When the vapor pressure is in this range, the filling properties are further improved. When the vapor pressure at an atmosphere temperature is more than 0.4 MPa, the effect of eliminating air bubbles tends not to be sufficiently obtained. On the other hand, when the vapor pressure at an atmosphere temperature is lower than 0.1 MPa, the pressure must be reduced, and hence, the apparatus tends to be complicated.

Although not particularly limited, the atmosphere temperature of the mold contact step is preferably 20° C. to 25° C.

As the condensable gas, for example, there may be mentioned Freons including a chlorofluorocarbon (CFC), such as trichlorofluoromethane; a hydrofluorocarbon (HFC), such as a fluorocarbon (FC), a hydrochlorofluorocarbon (HCFC), or 1,1,1,3,3-pentafluoropropane (CHF₂CH₂CF₃, HFC-245fa, PFP); and a hydrofluoro ether (FIFE), such as pentafluoro methyl ether (CF₃CF₂OCH₃, HFE-245mc).

Among those mentioned above, since the filling properties at an atmosphere temperature of 20° C. to 25° C. of the mold contact step are excellent, 1,1,1,3,3-pentafluoropropane (vapor pressure at 23° C.: 0.14 MPa, boiling point: 15° C.), trichlorofluoromethane (vapor pressure at 23° C.: 0.1056 MPa, boiling point: 24° C.), and pentafluoro methyl ether are preferable. Furthermore, since excellent in safety, 1,1,1,3,3-pentafluoropropane is particularly preferable.

The condensable gasses may be used alone, or at least two types thereof may be used in combination. In addition, those condensable gasses each may be used by mixing with a non-condensable gas, such as air, nitrogen, carbon dioxide, helium, or argon. As the non-condensable gas to be mixed with a condensable gas, in view of the filling properties, helium is preferable. Helium is able to pass through the mold 104. Hence, when gases (a condensable gas and helium) in an atmosphere are filled in the concave portion of the fine pattern formed in the mold 104 together with (part of) the coating film 106 in the mold contact step, the condensable gas is liquefied, and at the same time, helium passes through the mold.

<Alignment Step [3]>

Next, if needed, as shown in FIG. 1C, the position of the mold and/or that of the substrate to be processed are adjusted so that a mold-side alignment mark 105 and an alignment mark 103 of the substrate to be processed coincide with each other.

In this step, by the use of a photocurable composition in which the particle number concentration (/mL) of particles having a particle diameter of 0.07 μm or more is less than 310/mL and which is one type of liquid material L according to this embodiment, damage done to the mold caused by particles can be suppressed. In addition, pattern defects of a cured product pattern to be obtained can be reduced. As a result, the decrease in yield of the nanoimprint process can be suppressed.

<Light Irradiation Step [4]>

Next, as shown in FIG. 1D, while the alignment is performed in the step [3], a contact portion between the photocurable composition 1.01 and the mold 104 is irradiated with light through the mold 104. In more particular, the coating film 106 filled in the fine pattern of the mold is irradiated with light through the mold 104 ((d-1) of FIG. 1D). Accordingly, the coating film 106 filled in the fine pattern of the mold 104 is cured by the light thus irradiated, so that a cured product 108 is formed ((d-2) of FIG. 1D).

In this step, the light to be irradiated on the photocurable composition 101 forming the coating film 106 filled in the fine pattern of the mold 104 is selected in accordance with the sensitivity wavelength of the photocurable composition 101. In particular, for example, ultraviolet rays having a wavelength of 150 to 400 nm, X-rays, or electron rays may be appropriately selected.

Among those mentioned above, in particular, the light (irradiation light 107) to be irradiated on the photocurable composition 101 is preferably ultraviolet rays. The reason for this is that many compounds having sensitivity to ultraviolet rays are available on the market as a curing auxiliary agent (photopolymerization initiator). In this step, as a light source radiating ultraviolet rays, for example, there may be mentioned a high pressure mercury lamp, a ultrahigh pressure mercury lamp, a low pressure mercury lamp, a deep-UV lamp, a carbon arc lamp, a chemical lamp, a metal halide lamp, a xenon lamp, a KrF excimer laser, an ArF excimer laser, or a F₂ excimer laser, and a ultrahigh pressure mercury lamp is particularly preferable. In addition, the number of light sources to be used may be either one or at least two. In addition, when light irradiation is performed, the coating film 106 filled in the fine pattern of the mold may he entirely or partially irradiated with light.

In addition, the light irradiation may be intermittently performed on the entire region of the substrate a plurality of times or may be continuously performed on the entire region. Furthermore, after a partial region A is irradiated in a first irradiation step, a region B other than the region A may then be irradiated in a second irradiation step.

<Mold Release Step [5]>

Next, the cured film 108 is released from the mold 104. In this step, a cured film (a cured product pattern 109) having a predetermined pattern shape is formed on the substrate 102.

In this step (mold release step), as shown in FIG. 1E, the cured film 108 is released from the mold 104, and in the step [4] (light irradiation step), the cured product pattern 109 having a pattern shape which is a reverse pattern of the fine pattern formed in the mold 104 is obtained.

In addition, in the case in which the mold release step is performed in a condensable gas atmosphere, when the cured film 108 is released from the mold 104 in the mold release step, the condensable gas is evaporated in concomitance with the decrease in pressure at the interface at which the cured film 108 is in contact with the mold 104. As a result, an effect of reducing a releasing force required to release the cured film 108 from the mold 104 tends to be obtained.

A method for releasing the cured film 108 from the mold 104 is not particularly limited as long as the cured film 108 is not physically damaged when being released, and for example, the various conditions thereof are also not particularly limited. For example, while the substrate 102 (substrate to be processed) is fixed, peeling may be performed by moving the mold 104 in a direction apart from the substrate 102. Alternatively, while the mold 104 is fixed, peeling may be performed by moving the substrate 102 in a direction apart from the mold. Furthermore, the peeling may be performed by pulling the substrate 102 and the mold 104 in exactly opposite directions.

By the sequential process (manufacturing process) including the step [1] to the step [5] described above, a cured film having a desired concave-convex pattern shape (pattern shape derived from the concave-convex shape of the mold 104) at a desired position can be obtained. The cured film thus obtained can be used as an optical member (including the case in which the cured film is used as one member of the optical member), such as a Fresnel lens or a diffraction lattice. In the case as described above, an optical member including at least the substrate 102 and the cured product pattern 109 having a pattern shape arranged on this substrate 102 may be obtained.

In a method for manufacturing a film having a pattern shape according to this embodiment, a repeating unit (shot) including the step [1] to the step [5] can be repeatedly performed a plurality of times on the same substrate to be processed. By repeatedly performing the repeating unit (shot) including the step [1] to the step [5], a cured film can be obtained which has a plurality of desired concave-convex pattern shapes (pattern shapes each derived from the concave-convex shape of the mold 104) at desired positions of the substrate to be processed.

<Residual Film Removing Step [6] of Removing Part of Cured Film>

Although the cured film obtained in the mold release step, which is the step [5], has a specific pattern shape, in a region other than the region in which the pattern shape is formed, the cured film may partially remain in some cases (hereinafter, the part of the cured film as described above is called “residual film”). In the case as described above, as shown in FIG. 1F, from the cured film having a pattern shape thus obtained, a cured film (residual film) present in the region in which the cured film should be removed is removed. Accordingly, a cured product pattern 110 having a desired concave-convex pattern shape (pattern shape derived from the concave-convex shape of the mold 104) can be obtained.

In this step, as a method for removing a residual film, for example, there may be mentioned a method in which a cured film (residual film) which is a concave portion of the cured product pattern 109 is removed by an etching method or the like to expose the surface of the substrate 102 at the concave portion of the pattern of the cured product pattern 109.

When the cured film present at the concave portion of the cured product pattern 109 is removed by etching, a concrete method therefor is not particularly limited, and a known related method, such as a dry etching method, may be used. For the dry etching, a related known dry etching apparatus may be used. In addition, although a source gas used in the dry etching may be appropriately selected in accordance with the element composition of the cured film, a halogen gas, such as CF₄, C₃F₆, CO₂F₂, CBrF₃, BCl₃, PCl_{S}, SF_{G}, or Cl₂; a gas containing an oxygen atom, such as O₂, CO, or CO₂; an inert gas, such as He, N₂, or Ar; or a gas, such as H₂ or NH₃, may be used. In addition, those gases may be used in combination.

In addition, when the substrate 102 (substrate to be processed) is a substrate having an improved adhesion to the cured film 108 by a surface treatment, such as a silane coupling treatment, a silazane treatment, or a film formation of an organic thin film, after the cured film (residual film) present at the concave portion of the cured product pattern 109 is etched out, the surface treatment layer described above may also be removed by etching.

By the manufacturing process including the step [1] to the step [6] described above, a cured product pattern 110 having a desired concave-convex pattern shape (pattern shape derived from the concave-convex shape of the mold 104) at a desired position can be obtained, and a product having a cured film pattern can be obtained. Furthermore, when the substrate 102 is processed using the cured product pattern 110 thus obtained, the following substrate processing step (step [7]) is performed.

In addition, when the cured product pattern 110 thus obtained is used as an optical member (including the case in which the cured product pattern 110 is used as one member of the optical member), such as a diffraction lattice or a polarization plate, an optical component may also be obtained. In the case as described above, an optical component including at least the substrate 102 and the cured product pattern 110 arranged on this substrate 102 may be obtained.

<Substrate Processing Step [7]>

The cured product pattern 110 having a concave-convex pattern shape obtained by the method for manufacturing a cured film having a pattern shape according to this embodiment may be used as an interlayer insulating film included in an electronic component, such as a semiconductor element. In addition, the cured product pattern 110 may also be used as a resist film in semiconductor element manufacturing. As the semiconductor element in this case, for example, an LSI, a system LSI, a DRAM, an SDRAM, an RDRAM, or a D-RDRAM may be mentioned.

When the cured product pattern 110 is used as a resist film, for example, etching or ion implantation is performed on part of the substrate (region denoted by reference numeral 111 in FIG. 1F) at which the surface thereof is exposed by an etching step which is the step [6]. In addition, in this step, the cured product pattern 110 functions as an etching mask. In addition, since an electronic component is formed, a circuit structure 112 (FIG. 1G) based on the pattern shape of the cured product pattern 110 can be formed on the substrate 102. Hence, a circuit board to be used in a semiconductor element or the like can be manufactured. In addition, when this circuit board is connected to a circuit control mechanism therefor, an electronic apparatus, such as a display, a camera, or a medical apparatus, may also be formed.

In addition, as is the case described above, by the use of the cured product pattern 110 as a resist film, for example, when etching or ion implantation is performed, an optical component may also be obtained.

In addition, when a substrate provided with a circuit or an electronic component is formed, the cured product pattern 110 may be finally removed from a processed substrate, the structure may also be formed so that the cured product pattern 110 remains as a member forming an element.

By the manufacturing process including the step [1] to the step [7], the circuit structure 112 having a desired concave-convex pattern shape (pattern shape derived from the concave-convex shape of the mold 104) at a desired position can be obtained, and a product having a circuit structure can be obtained. In addition, by arbitrarily using a cured layer forming composition (composition (2)), which is one type of liquid material L according to this embodiment described above, in accordance with the purpose, the following cured layer forming step (step [α]) may be performed.

<Cured Layer Forming Step [α]>

A cured layer obtained by the cured layer forming step which is the step [α] may include an adhesion layer, an underlayer, an intermediate layer, a topcoat layer, or a smooth layer but is not limited thereto.

As long as those cured layers are each provided to form a laminate, the position of the cured layer can be arbitrarily selected by the timing at which this step [α] is performed. For example, the cured layer may be formed on the substrate 102 before the arrangement step [1] or may be formed on the cured product pattern 109 after the mold release step [5]. Alternatively, the cured layer may be formed on the cured product pattern 110 and/or the substrate portion 111 at which the surface of the substrate is exposed after the residual film removing step [6] or may be formed on the circuit structure 112 after the substrate processing step [7].

In addition, those cured layers may be formed alone, or at least two types thereof may be laminated to each other.

For example, in the mold release step [5], when the cured layer is formed in order to release the mold preferentially at the mold-resist interface than at the substrate-resist interface, an adhesion layer is preferably formed as the cured layer between the substrate and the resist.

In this case, before the arrangement step [1], by this step [α], the composition (2), which is one type of liquid material L according to this embodiment, is applied to the substrate 102 to form the cured layer (adhesion layer).

The substrate 102 on which the photocurable composition 101 is arranged is a substrate to be processed, and in general, a silicon wafer is used. Since a silanol group is present on the surface of a silicon wafer, the composition (2) is preferably a composition which forms a chemical bond with a silanol group by a heat treatment but is not limited thereto.

However, in this embodiment, the substrate 102 is not limited to a silicon wafer and may be arbitrarily selected from known semiconductor device-purpose substrates formed of aluminum, a titanium-tungsten alloy, an aluminum-silicon alloy, an aluminum-copper-silicon alloy, a silicon oxide, and a silicon nitride. As the substrate described above, there may also be used a substrate on which at least one type of film of a spin-on-glass, a spin-on-carbon, an organic substance, a metal, an oxide, a nitride, or the like is formed.

As a method for applying the composition (2) on the substrate, for example, an inkjet method, a dip coating method, an air-knife coating method, a curtain coating method, a wire-bar coating method, a gravure coating method, an extrusion coating method, a spin coating method, or a slit scanning method may be used. In view of coatability, and in particular, in view of film thickness uniformity, a spin coating method is particularly preferable.

After the composition (2) is applied, the solvent (E) is evaporated (dried), so that a uniform cured layer is formed. In particular, when the component (D) is a polymerizable compound, while the solvent (E) is evaporated, a polymerization reaction may be simultaneously performed so as to form a uniform cured layer. In this step, heating is preferably performed. Although a preferable temperature is appropriately selected in consideration of the reactivity of the component (D) and the boiling points of the component (D) and the solvent (E), the temperature is preferably 70° C. to 250° C. The temperature is more preferably 100° C. to 220° C. and further preferably 140° C. to 220° C. In addition, the evaporation of the solvent (E) and the reaction of the component (D) may be performed at different temperatures.

Although the thickness of the cured layer formed by applying the composition (2) according to this embodiment on the substrate is varied depending on the use application, for example, the thickness is preferably 0.1 to 100 nm. The thickness is more preferably 0.5 to 60 nm and further preferably 1 to 10 nm.

In addition, when the cured layer is formed by applying the composition (2) according to this embodiment on the substrate, the formation may be performed by a multiple coating technique. In addition, the cured layer to be formed is preferably flat as much as possible. The roughness of the surface is preferably 1 nm or less.

### EXAMPLES

Hereinafter, although the present invention will be described in detail with reference to Examples, the technical scope of the present invention is not limited to the following Examples.

### Comparative Example 1

(1) Preparation of Curable Composition (b-1)

First, the following component (A), component (B), and addition component (C) were blended together, and in a class 100 polypropylene bottle, a curable composition (b-1) of Comparative Example 1 was prepared.

(1-1) Component (A): Total 94 Parts by Weight

<A-1> isobornyl acrylate (trade name: IB-XA, manufactured by Kyoeisha Chemical Co., Ltd.): 9.0 parts by weight

<A-2> benzyl acrylate (trade name: V#160, manufactured by Osaka Organic Industry Ltd.): 38.0 parts by weight

<A-3> neopentyl glycol diacrylate (trade name: NP-A, manufactured by Kyoeisha Chemical Co., Ltd): 47.0 parts by weight

(1-2) Component (B): Total 3 Parts by Weight

<B-1> Lucirin TPO (manufactured by BASF) (Formula (0): 3 parts by weight

(1-3) Addition Component (C) Other than Component (A) and Component (B): Total 2.1 Parts by Weight

<C-1> SR-730 (manufactured by Aoki Oil Industrial Co., Ltd.) (Formula (i)): 1.6 parts by weight

<C-2>4,4′-bis(diethylamine)benzophenone (manufactured by Tokyo Chemical Industry Co., Ltd.) (Formula (g)): 0.5 parts by weight

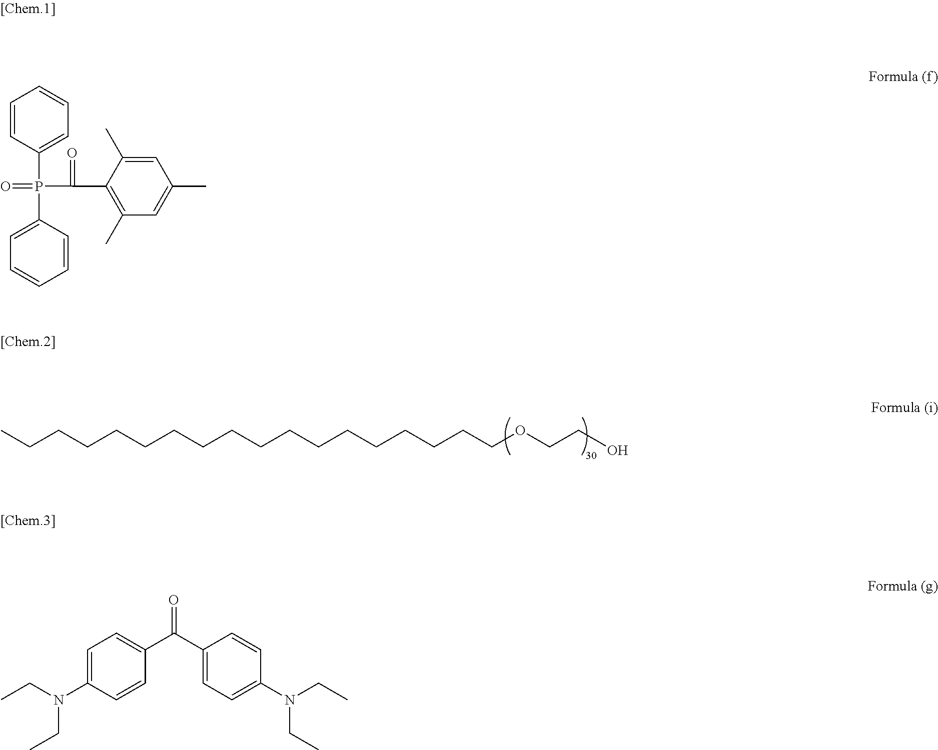

(2) Measurement of Particle Number Concentration of Particles in Curable Composition (b-1)

The measurement of particle number concentration of particles in a curable composition in each of Examples and Comparative Examples was performed using a liquid-borne particle sensor KS-41B (with option for 0.07-μm size particle, manufactured by Rion Co., Ltd.). However, since a purification step, such as filtration, was not performed on the curable composition (b-1) of this Comparative Example, the particle number concentration of particles thereof is estimated remarkably high. When the measurement of particle number concentration of particles in the curable composition (b-1) as described above is performed, a measurement cell and a flow path of the liquid-home particle sensor are probably seriously contaminated by the particles. Hence, the measurement of particle number concentration of particles in the curable composition (b-1) was not performed.

However, it is believed that the particle number concentration of particles having a particle diameter of 0.07 μm or more in the curable composition (b-1) significantly exceeds the maximum rated particle number concentration (9,600/mL) of the liquid-borne particle sensor used for the measurement.

### Comparative Example 2

(1) Preparation of Curable Composition (b-2)

After the curable composition (b-1) of Comparative Example 1 was prepared, a pressure filtration was performed using the purification system shown in FIG. 3B, so that a curable composition (b-2) was obtained. In this step, as a filter of the purification device 11, a filter having a pore diameter of 5 nm (Optimizer D300, manufactured by Nihon Entegris K.K.) was used. By applying a pressure to the inside of a pressure tank 16 by the pressure system 17, the curable composition (b-1) in the container 14 was transported to the purification device 11, so that a pressure filtration was performed. In addition, in this case, a regulator (not shown) of the pressure tank 16 was adjusted in a range of 0.05 to 0.10 MPa so that the curable composition (b-1) was allowed to pass through the filter at an average flow rate of 9 mL/mint.

By the use of a class 100 polypropylene bottle as the recovery container 13, all flow fractions including the initial flow fraction were recovered in the recovery container 13. As described above, the curable composition (b-2) of Comparative Example 2 was prepared.

(2) Measurement of Particle Number Concentration of Particles in Curable Composition (h-2)

The measurement of particle number concentration of particles in the curable composition (b-2) thus prepared was performed using a liquid-borne particle sensor KS-41B (with an option for 0.07-μm size particle, manufactured by Rion Co., Ltd.). In addition, a controller KE-40B1 (manufactured by Rion Co., Ltd.) and a syringe sampler KZ-30W1 (manufactured by Rion Co., Ltd.) were also used together therewith. By driving the syringe sampler, 10 mL of the curable composition (b-2) was transported so as to pass through a measurement cell of the liquid-borne particle sensor at a flow rate of 5 mL/actin. By the method described above, the particle number concentration of particles having a particle diameter of 0.07 μm or more in the curable composition (b-2) was measured. The operation described above was repeatedly performed three times, and the average value was obtained from the particle number concentrations thus measured and was regarded as the particle number concentration (average) of particles having a particle diameter of 0.07 μm or more. The particle number concentration (average) of particles having a particle diameter of 0.07 μm or more in the curable composition (b-2) was 616/mL.

In addition, every measurement of the particle number concentration of particles in the present specification was performed after the light scattering LPC was calibrated in advance using polystyrene latex (PSL) standard particles which had a known particle diameter and which were dispersed in purified water. In addition, immediately after the measurement, it was confirmed using a pulse height-analysis software KF-50A (manufactured by Rion Co., Ltd.) that the accuracy of the measurement value of the particle number concentration of particles having a particle diameter of 0.07 μm or more was sufficiently ensured. In particular, the ratio (s/n) of a light receiving-element voltage s of scattering light of an aqueous solution containing 0.07 μm PSL particles to a light receiving-element voltage n of scattering light of a measurement solution was obtained, and it was confirmed that the ratio was sufficiently larger than L3.

### Comparative Example 3

(1) Preparation of Curable Composition (b-3)

After the curable composition (b-1) of Comparative Example 1 was prepared, a pressure filtration was performed using the purification system shown in FIG. 3B, so that a curable composition (b-3) was obtained. In this step, as a filter of the purification device 11, a filter having a pore diameter of 5 nm (Optimizer D300, manufactured by Nihon Entegris K.K.) was used. By applying a pressure to the inside of the pressure tank 16 by the pressure system 17, the curable composition (b-1) in the container 14 was transported to the purification device 11, so that a pressure filtration was performed. In addition, in this case, the regulator (not shown) of the pressure tank 16 was adjusted in a range of 0.05 to 0.10 MPa so that the curable composition (b-1) was allowed to pass through the filter at an average flow rate of 9 mL/min.

A class 100 polypropylene bottle was used as the recovery container 13. A flow fraction in an amount of approximately 200 mL from the start of passing of the curable composition (b-1) through the filter was regarded as an initial flow fraction, and this initial flow fraction was received in the waste liquid container 15 not in the recovery container 13. Subsequently, the filtration was further continued, a liquid obtained by the filtration was recovered in the recovery container 13. In addition, a final flow fraction in which bubbles were confirmed by visual inspection was not received in the recovery container 13 but in the waste liquid container 15. As described above, the curable composition (b-3) of Comparative Example 3 was prepared.

(2) Measurement of Particle Number Concentration of Particles in Curable Composition (b-3)

When the particle number concentration of particles was measured in a manner similar to that of Comparative Example 2, the particle number concentration (average) of particles having a particle diameter of 0.07 μm or more in the curable composition (b-3) was 444/mL.

### Comparative Example 4

(1) Preparation of Curable Composition (b-4)

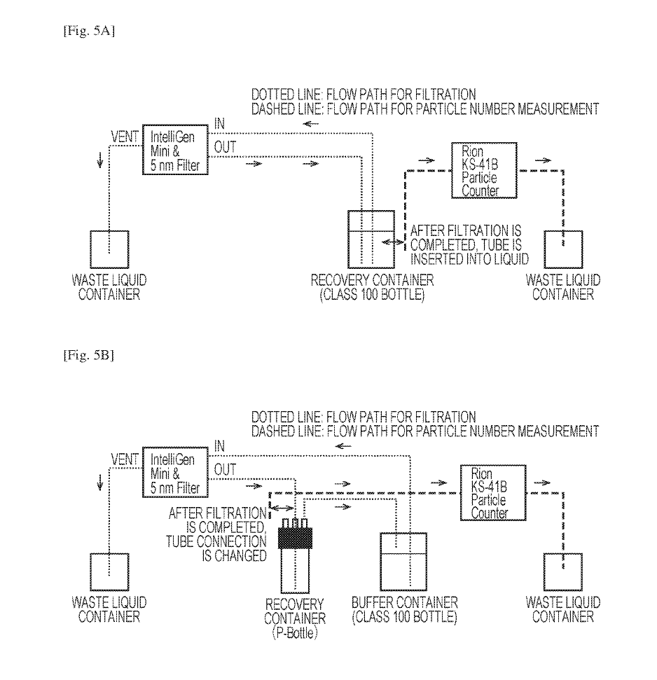

After the curable composition (b-3) of Comparative Example 3 was prepared, a cycle filtration was performed using a purification system shown in FIG. 5A, so that a curable composition (b-4) was obtained. In this step, as a filter of a purification device, a filter having a pore diameter of 5 nm (Impact Mini, manufactured by Nihon Entegris K.K.) was used. By a dispensing device (IntelliGen Mini, manufactured by Nihon Entegris K. K.) of the purification device shown in FIG. 5A, the curable composition (b-3) received in a container was transported to the purification device, so that a cycle filtration was performed. In this step, by the use of compressed nitrogen at a pressure of (127 MPa, the dispensing device was set so that the curable composition (b-3) was allowed to pass through the filter at an average flow rate of 4.5 mL/min.

A class 100 polypropylene bottle was used as a recovery container. First, a liquid in the flow path was replaced with approximately 180 mL of the curable composition (h-3). Next, a flow fraction in an amount of approximately 180 mL from the start of passing of the curable composition (b-3) through the filter was regarded as an initial flow fraction, and this initial flow fraction was received in a waste liquid container so as not to be mixed in a targeted flow fraction. Subsequently, a cycle filtration was carried out using the dispensing device in such a way that 9 mL of the curable composition (b-3) was dispensed 280 times. Accordingly, the targeted flow fraction (curable composition (b-4)) was obtained in the class 100 polypropylene bottle. As described above, the curable composition (b-4) of Comparative Example 4 was prepared.

(2) Measurement of Particle Number Concentration of Particles in Curable Composition (b-4)

When the particle number concentration of particles was measured in a manner similar to that of Comparative Example 2, the particle number concentration (average) of particles having a particle diameter of 0.07 μm or more in the curable composition (b-4) was 889/mL.

### Example 1

(1) Preparation of Curable Composition (a-1)

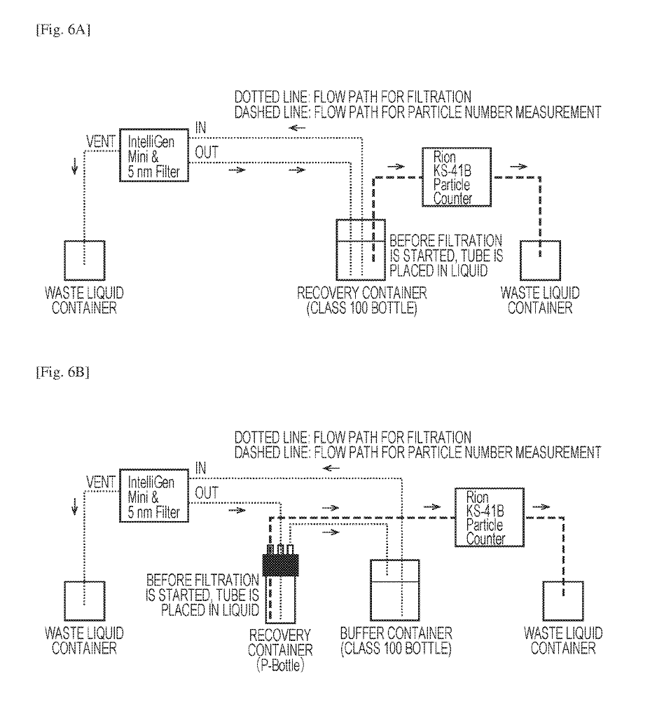

After the curable composition (b-3) of Comparative Example 3 was prepared, a cycle filtration was performed in a manner similar to that of Comparative Example 4. In this step, as shown in FIG. 6A, before the cycle filtration was performed, a front end of a liquid sampling tube of a particle sensor was placed in advance in the curable composition (b-3). As described above a curable composition (a-1) of Example 1 was prepared.

(2) Measurement of Particle Number Concentration of Particles in Curable Composition (a-1)

Except that before the cycle filtration was started, the front end of the liquid sampling tube of the particle sensor was placed in advance in a liquid to be formed into the curable composition (a-1), the particle number concentration of particles was measured in a manner similar to that of Comparative Example 2. The particle number concentration (average) of particles having a particle diameter of 0.07 μm or more in the curable composition (a-1) was 99.9/mL.

### Example 2

(1) Preparation of Curable Composition (a-2)

Except that after the curable composition (b-3) of Comparative Example 3 was prepared, the dispensing number was set to 12.0 times, a cycle filtration was performed in a manner similar to that of Example I, and a targeted flow fraction (curable composition (a-2)) was obtained in a class 100 polypropylene bottle (FIG. 6A). As described above, the curable composition (a-2) of Example 2 was prepared.

(2) Measurement of Particle Number Concentration of Particles in Curable Composition (a-2)

The particle number concentration of particles was measured in a manner similar to that of Example 1. The particle number concentration (average) of particles having a particle diameter of 0.07 μm or more in the curable composition (a-2) was 303/mL.

### Comparative Example 5

(1) Preparation of Curable Composition (b-5)

Except that after the curable composition (b-3) of Comparative Example 3 was prepared, a P-bottle was used for a cycle filtration, the cycle filtration was performed in a manner similar to that of Comparative Example 4, and a targeted flow fraction (curable composition (b-5)) was obtained in the P-bottle (FIG. 5B). As described above, the curable composition (b-5) of Comparative Example 5 was prepared.

As the P-bottle, a bottle formed of a high purity PFA-made 120-mL column forming container (manufactured by Savillex) and a column forming lid (number of tube ports: 3, special ordered product manufactured by Savillex) was used. This bottle was sufficiently washed with EL grad isopropyl alcohol (manufactured by Kanto Chemical Co., Inc.) before the use. The P-bottle is a bottle which can change pipe arrangement by connecting a tube to one of the ports of the lid. In addition, in this case, the change of the tube is performed by tightening or loosening a screw of the port. By the operation described above, in the P-bottle, particles may be generated in some cases.

(2) Measurement of Particle Number Concentration of Particles in Curable Composition (b-5) Except that the particle number concentration of particles in the P-bottle was measured, the particle number concentration of particles was measured in a manner similar to that of Comparative Example 4. The particle number concentration (average) of particles having a particle diameter of 0.07 μm or more in the curable composition (b-5) was 3,268/mL.

### Example 3

(1) Preparation of Curable Composition (a-3)

After the curable composition (b-3) of Comparative Example 3 was prepared, except that before a cycle filtration was started, the front end of the liquid sampling tube of the particle sensor was connected as a long tube of the P-bottle, the cycle filtration was performed in a manner similar to that of Comparative Example 5. Accordingly, a targeted flow fraction (curable composition (a-3)) was obtained in the P-bottle (FIG. 613). As described above, the curable composition (a-3) of Example 3 was prepared.

(2) Measurement of Particle Number Concentration of Particles in Curable Composition (a-3)

Except that before the cycle filtration was started, the front end of the liquid sampling tube of the particle sensor was placed in advance in a liquid to be formed into the curable composition (a-3), the particle number concentration of particles was measured in a manner similar to that of Comparative Example 5. The particle number concentration (average) of particles having a particle diameter of 0.07 μm or more in the curable composition (a-3) was 56.1/mL.

### Reference Example 1

(1) Preparation of Monomer Liquid (c-1)

Except that isobornyl acrylate (trade name: IB-XA, manufactured by Kyoeisha Chemical Co., Ltd.) was used instead of using the curable composition (b-1), a pressure filtration was performed in a manner similar to that of Comparative Example 3, and a targeted flow fraction (monomer liquid (c-1)) was obtained in a class 100 polypropylene bottle. As described above, the monomer liquid (c-1) of Reference Example 1 was prepared.

(2) Measurement of Particle Number Concentration of Particles in Monomer Liquid (c-1)

The particle number concentration of particles was measured in a manner similar to that of Comparative Example 2. The particle number concentration (average) of particles having a particle diameter of 0.07 μm or more in the monomer liquid (c-1) was 79.5/mL.

The results of Examples, Comparative Examples, and Reference Example are collectively shown in Tables 1 and 2.

TABLE 1

| | | | | | | | | | Particle number |
|---|---|---|---|---|---|---|---|---|---|
| | | | | Preparation process | | | | | concentration |
| | | | | | Pressure | | Cycle | | particles (/mL) |
| | | | Bottle | | filtration/ | | filtration/ | Connection | Total of particles |
| | | | for | | Removal | | Removal | change | having a |
| | | | targeted | | of initial | | of initial | operation | particle |
| | | | flow | Pressure | flow | Cycle | flow | after | diameter of 0.07 μm |
| | Material | Number | fraction | filtration | fraction | filtration | fraction | filtration | or more |
| Comparative | Curable | b-1 | PP100 | x | — | x | — | — | — |
| Example 1 | composition | | | | | | | | |
| Comparative | Curable | b-2 | PP100 | ∘ | x | x | — | ∘ | 616 |
| Example 2 | composition | | | | | | | | |
| Comparative | Curable | b-3 | PP100 | ∘ | ∘ | x | — | ∘ | 444 |
| Example 3 | composition | | | | | | | | |
| Comparative | Curable | b-4 | PP100 | ∘ | ∘ | ∘ | ∘ | ∘ | 889 |
| Example 4 | composition | | | | | | | | |
| Comparative | Curable | b-5 | P | ∘ | ∘ | ∘ | ∘ | ∘ | 3268 |
| Example 5 | composition | | | | | | | | |
| Example 1 | Curable | a-1 | PP100 | ∘ | ∘ | ∘ | ∘ | x | 99.9 |
| | composition | | | | | | | | |
| Example 2 | Curable | a-2 | PP100 | ∘ | ∘ | ∘ | ∘ | x | 303 |
| | composition | | | | | | | | |
| Example 3 | Curable | a-3 | P | ∘ | ∘ | ∘ | ∘ | x | 56.1 |
| | composition | | | | | | | | |
| Reference | Monomer | c-1 | PP100 | ∘ | ∘ | x | — | ∘ | 79.5 |
| Example 1 | | | | | | | | | |

TABLE 2

| | Particle number concentration (average) of particles [/mL] | | | | | | | | | | |
|---|---|---|---|---|---|---|---|---|---|---|---|
| | Differential in particle diameter [μm] | | | | | | | | | | Total |
| | 0.07~0.09 | 0.09~0.1 | 0.1~0.12 | 0.12~0.13 | 0.13~0.15 | 0.15~0.18 | 0.18~0.2 | 0.2~0.3 | 0.3~0.5 | 0.5~ | 0.07~ |
| Comparative Example 1 | — | — | — | — | — | — | — | — | — | — | — |
| Comparative Example 2 | 334 | 86 | 90 | 30 | 31 | 20 | | 24 | | | 616 |
| Comparative Example 3 | 221 | 58 | 53 | 21 | 24 | 14 | 5 | 12 | 6 | 30 | 444 |
| Comparative Example 4 | 652 | 85 | 67 | 24 | 26 | 12 | 5 | 9 | 4 | 6 | 889 |
| Comparative Example 5 | 1816 | 483 | 452 | 167 | 176 | 76 | 27 | 45 | 11 | 16 | 3268 |
| Example 1 | 63.3 | 12.9 | 12.7 | 3.3 | 2.7 | 1.6 | 0.6 | 1.3 | 0.4 | 1.1 | 99.9 |
| Example 2 | 175 | 45 | 39 | 13 | 13 | 5 | 2 | 4 | 1 | 7 | 303 |
| Example 3 | 30.1 | 9.3 | 7.1 | 3.2 | 2.7 | 1.5 | 0.5 | 0.9 | 0.1 | 0.7 | 56.1 |
| Reference Example 1 | 58.8 | 9.2 | 6.3 | 1.8 | 1.2 | 0.6 | 0.3 | 0.5 | 0.1 | 0.7 | 79.5 |

First, from the comparison between Comparative Example 1 and Comparative Example 2, it was found that even by the simple filtration purification step in which the pressure filtration was performed only once, the particle number concentration of particles in the liquid material L could be significantly decreased.

Next, from the comparison between Comparative Example 2 and Comparative Example 3, it was found that when the initial flow fraction and the final flow fraction were configured not to be mixed in the targeted flow fraction in the pressure filtration, the particle number concentration of particles in the liquid material L could be further decreased. However, the particle number concentration of particles of the curable composition (b-3) obtained in Comparative Example 3 was not sufficient as a nanoimprint liquid material.

Next, from the comparison among Comparative Example 3, Example 1, and Example 2, it was found that by the use of the cycle filtration step, the particle number concentration of particles in the liquid material L could be more effectively decreased. In Example 2, the particle number concentration of particles having a particle diameter of 0.07 μm or more was decreased to less than 310/mL. In addition, in Example 1 in which the number of cycle filtrations was approximately two times that of Example 2, the particle number concentration of particles having a particle diameter of 0.07 μm or more was decreased to less than 137/mL.

Furthermore, from the comparison among Comparative Example 4, Example 1, and Example 2, it was found that in the cycle filtration step, the connection change operation of the recovery container was preferably not performed during and after the filtration of the crude liquid material L. That is, in Comparative Example 4, the connection of the pipe was changed after the cycle filtration was completed, and the tube connecting the measurement system (particle sensor) was placed in the curable composition (13-4). On the other hand, in Example 1 and Example 2, by the use of the measurement system connected in advance to the recovery container, the particle number concentration of particles was measured without changing the connection of the pipe after the cycle filtration was completed. As a result, the particle number concentration of particles in Example 1 could be decreased to approximately one ninth of that of Comparative Example 4.

On the other hand, from the comparison between Comparative Example 4 and Comparative Example 5, it was found that even if the cycle filtration step was performed as was the case described above, when the P-bottle having a complicated structure including tubes, ports, and the like was used instead of using a class 100 bottle having a simple structure, the decrease in particle number concentration of particles could not be easily performed. In the case of Example 3, even by the use of the P-bottle which could not easily decrease the particle number concentration of particles, when the particle removing step according to this embodiment was performed, the particle number concentration of particles having a particle diameter of 0.07 μm or more could be significantly decreased.

Furthermore, after an approximate curve was formed based on the relationship between the (cumulative) particle number concentration Y of particles in the curable composition (a-3) of Example 3 and a particle diameter X (μm), the particle number concentration of particles having a measurable minimum particle diameter (0.07 μm) or less by the particle sensor was calculated. When an approximate curve was formed from four points represented by X=0.12, X=0.1, X=0.09, and X=0.07 shown in Table 3, Y=8.587×10⁻³X^{-3.308} (R²=0.9972) was obtained. In addition, in Table 3, Differential represents the particle number concentration of particles having particle diameters in each particle diameter range, and Cumulative represents the cumulative particle number concentration of particles having a particle diameter equal to or more than the minimum particle diameter in each particle diameter range. For example, the figure of the column of Differential on the line in which the particle diameter X is 0.042 to 0.07 indicates the particle number concentration of particles having a particle diameter of 0.042 to less than 0.07 μm. As is the case described above, the figure of the column of Cumulative on the same line indicates the particle number concentration of particles having a particle diameter of 0.042 μm or more. When calculation was performed using this approximate curve, it was found that in the curable composition (a-3) of Example 3, the particle number concentration of particles having a particle diameter of 0.042 μm or more was 307.7/mL and was less than 310/mL.

TABLE 3

Particle number
concentration Y of particles (/mL)

| Particle diameter X (μm) | Differential | Cumulative |
|---|---|---|
| 0.042~0.07 | 250.9 | 307.7 |
| 0.07~0.09 | 32.1 | 56.8 |
| 0.09~0.1 | 7.2 | 24.7 |
| 0.1~0.12 | 8.0 | 17.5 |
| 0.12~ | 9.5 | 9.5 |

For reference, from the comparison between Reference Example 1 and Comparative Example 3, it was found that when isobornyl acrylate, which was one component of the liquid material L, was used, the particle number concentration of particles could be significantly decreased than that of the case in which the liquid material L itself was used. That is, when the composition formed by mixing a plurality of components was used as was this example, it becomes difficult to decrease the particle number concentration of particles. However, in this example, when the liquid material L was manufactured by a manufacturing method including the purification step according to this embodiment, the particle number concentration of particles could be significantly decreased.

As described above, it is believed that when a nanoimprint liquid material in which the particle number concentration of particles having a particle diameter of 0.07 μm or more is less than 310/mL is used, the generation of damage to the mold caused by particles can be suppressed. In addition, it is also believed that pattern defects of a cured product pattern to be obtained can be reduced. As a result, it is believed that the decrease in yield of the nanoimprint process can be suppressed.

Furthermore, as described above, when a mold having an L/S pattern in which the width of the concave portion of the mold is S (nm) is used, it is believed that when the particle diameter D (nm) of a particle is larger than 3S (nm) (D>3S), the mold may be damaged. That is, in the case of particles having a particle diameter of 0.07 μm or more, as a mold pattern which may not be damaged, a pattern having a space width equivalent to or more than one third of the particle diameter, that is, a pattern having a space width of 23.3 nm or more, may be mentioned. That is, it is believed that in a nanoimprint process which uses a mold with a pattern having a minimum space width of 23.3 nm or more, in particular, the curable composition according to this embodiment can suppress the decrease in yield.

Furthermore, in the curable composition (a-3) of Example 3, the particle number concentration of particles having a particle diameter of 0.042 μm or more was less than 310/mL. From the result described above, in the case of the curable composition (a-3) of Example 3, it is believed that when a mold with a pattern having a space width of 14 nm or more, which is one third of a particle diameter of 0.042 μm or more, is used, the decrease in yield of the nanoimprint process can be suppressed.

### Example 4

(1) Preparation of Curable Composition (a-4)

Except that approximately 92 percent by weight of the acrylic monomer mixture, approximately 5 percent by weight of the photo initiator, and approximately 3 percent by weight of the surfactant, each of which was as same as or similar to each in the curable composition (h-1), were used, a curable composition (a-4) of Example 4 was prepared in a manner similar to that of Example 1.

(2) Measurement of Particle Number Concentration of Particles in Curable Composition (a-4)

The particle number concentration of particles was measured in a manner similar to that of Example 1. The particle number concentration (average) of particles having a particle diameter of 0.07 μm or more in the curable composition (a-4) was less than 100/mL.

(3) Observation of Nanoimprint Pattern

Next, by the method shown below, a cured product pattern was formed by a nanoimprint process using the curable composition (a-4). Subsequently, the cured product pattern thus formed was observed by an electron microscope (SEMVision manufactured by Applied Materials).

(3-1) Arrangement Step

On a 300-mm silicon wafer on which an adhesion layer having a thickness of 3 nm was formed, 1,440 liquid droplets (11 pL/one liquid droplet) of the curable composition (a-4) were dripped by an ink-jet method. In addition, when the liquid droplets were each dripped, dripping was performed in a region of the silicon wafer having a width of 26 mm and a length of 33 mm so that the intervals between the liquid droplets were equivalent to each other in the above region.

(3-2) Mold Contact Step, Light Irradiation Step

Next, a quartz mold (width: 26 mm, length: 33 mm) which was not surface-treated and in which a 28-nm line and space (L/S) pattern having a height of 60 nm was formed was brought into contact with the curable composition (a-4) on the silicon wafer.

Next, after 30 seconds from the start of the contact of the quartz mold, the curable composition (a-4) on the silicon wafer was irradiated with UV light through the quartz mold. In addition, in UV light irradiation, a UV light source (EXECURE 3000, manufactured by HOYA CANDEO OPTRONICS CORPORATION) having a 200-W mercury xenon lamp was used. In addition, in UV light irradiation, an interference filter (VPF-50C-10-25-31300, manufactured by SIGMAKOKI Co., Ltd.) selectively transmitting light having a wavelength of 313±5 nm was arranged between the UV light source and the quartz mold. In addition, the intensity of UV light immediately under the quartz mold was 40 mW/cm² at a wavelength of 313 nm. Under the conditions described above, a UV light exposure of 170 mJ/cm² was performed.

(3-3) Mold Release Step

Next, the quartz mold was pulled up at a rate of 0.5 mm/s so as to be separated from the cured product. When the quartz mold was released, a cured product pattern having an average thickness of 40.1 nm was formed on the silicon wafer.

(3-4) Observation of Cured Product Pattern Using Electron Microscope

The cured product pattern thus formed and a mask pattern of the quartz mold released in the mold release step were observed using an electron microscope. The observation was performed on a 6.75-μm square region of each of the cured product pattern and the mask pattern.

After adhesion layer-having silicon wafers were prepared on which particles having a particle diameter of 0.046 to 0.3 μm were present, the nanoimprint process (3-1 to 3-3) was performed on the region of each adhesion layer-having silicon wafer in which the particles were present so as to form a cured product pattern. Subsequently, the region of the mask pattern after the cured product was formed and the region of the cured product pattern each corresponding to the region in which the particles were present were observed by an electron microscope. The results are shown in Table 4.

In the cases in which particles having a particle diameter of 0.09 μm or more (0.09 μm, 0.1 μm, and 0.3 μm) were present, the mask pattern was damaged in every case. On the other hand, in the cases in which particles having a particle diameter of 0.08 μm or less (0.08 μm and 0.046 μm) were present, no damage to the mask pattern was observed.

in addition, in the cases in which particles having a particle diameter of 0.08 μm or more (0.08 μm, 0.09 μm, 0.1 μm, and 0.3 μm) were present, damage done to the cured product pattern was observed in every case. On the other hand, in the case in which particles having a particle diameter of 0.046 μm were present, damage and defects were not observed in the cured product pattern.

Furthermore, the formation of the cure product pattern by the nanoimprint process (3-1 to 3-3) was performed repeatedly on the region in which the particles were present, and the mask pattern and the cured product pattern were observed each time. As a result, in the case in which the particles having a particle diameter of 0.08 μm or more were present, defects having the same shape were observed at the same position of the cured product patterns in all the cases. On the other hand, in the case in which the particles having a particle diameter of 0.046 μm were present, damage and defects were not observed in the cured product pattern.

From the results described above, a particle diameter of slightly less than 0.08 μm is supposed to be the threshold at which whether a defect is generated or not in the cured product pattern by the presence of particles having the value described above.

As described above, it was actually confirmed that the result of the theoretical calculation based on the above hypothesis was correct, the hypothesis relating to the threshold of the particle diameter of particles contained in a nanoimprint process liquid material in order not to generate a defect in a cured product pattern formed by a nanoimprint process. That is, when a nanoimprint process liquid material in which the number of particles having a particle diameter of 0.07 μm or more is less than one per one wafer is used, the generation of damage to the mold caused by the particles can be suppressed. In addition, the pattern defect of the obtained cured product pattern can be suppressed. As a result, the decrease in yield of a nanoimprint process can be suppressed.

TABLE 4

| | Damage to mask | Damage/defect of cured product pattern | | |
|---|---|---|---|---|
| | pattern | | | Immediately |
| | Immediately | Immediately | Immediately | after performing |
| | after performing | after performing | after performing | nanoimprint |
| Particle diameter | nanoimprint | nanoimprint | nanoimprint | process three |
| of particles (μm) | process once | process once | process twice | times |
| 0.3 | Yes | Yes | Yes | Yes |
| 0.1 | Yes | Yes | Yes | Yes |
| 0.09 | Yes | Yes | Yes | Yes |
| 0.08 | — | Yes | Yes | Yes |
| 0.046 | — | No | — | — |

(Note)
In Table 4, “—” indicates that neither damage nor defect is observed or present.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-039399, filed Feb. 27, 2015, and No. 2016-030332, filed Feb. 19, 2016, which are hereby incorporated by reference herein in their entirety.

1. A liquid material for nanoimprint in which the particle number concentration of particles having a particle diameter of 0.07 μm or more is less than 310/mL.

2. The liquid material for nanoimprint according to claim 1, wherein the particle number concentration of particles having a particle diameter of 0.07 μm or more is less than 137/mL.

3. The nanoimprint liquid material for nanoimprint according to claim 1, wherein the liquid material for nanoimprint contains at least one of a monofunctional (meth)acrylic compound and a multifunctional (meth)acrylic compound.

4. The liquid material for nanoimprint according to claim 1, wherein the liquid material for nanoimprint contains a fluorine-based surfactant or a hydrocarbon-based surfactant.

5. The liquid material for nanoimprint according to claim 1, wherein the viscosity of the nanoimprint liquid material is 1 to 100 mPa s.

6. The liquid material for nanoimprint according to claim 1, wherein the liquid material for nanoimprint is a pattern forming curable composition.

7. The liquid material for nanoimprint according to claim 1, wherein the liquid material for nanoimprint is an adhesion layer forming composition.

8. A liquid material for nanoimprint to which a concave-convex pattern is transferred by a nanoimprint process using a mold having the concave-convex pattern in the surface thereof,
wherein when the width of a concave portion of the concave-convex pattern of the mold is S (nm), the particle number concentration of particles having a particle diameter of 2.5S (nm) or more is less than 310/mL.

9. The liquid material for nanoimprint according to claim 8, wherein the width (S) of the concave portion is 4 to less than 30 nm, and when the depth of the concave portion is H (nm), the aspect ratio (H/S) of the concave portion of the concave-convex pattern is 1 to 10.

10. A method for manufacturing a cured product pattern, the method comprising:
a first step of arranging the liquid material for nanoimprint according to claim 6 on a substrate;
a second step of bringing the liquid material for nanoimprint into contact with a mold;
a third step of irradiating the liquid material for nanoimprint with light to form a cured product; and
a fourth step of releasing the cured product from the mold.

11. The method for manufacturing a cured product pattern according to claim 10, further comprising a step of forming an adhesion layer from the liquid material for nanoimprint according to claim 7 on an upper surface of the substrate before the first step.

12. The method for manufacturing a cured product pattern according to claim 10, wherein the mold is a mold having a concave-convex pattern in the surface thereof,
the width of a concave portion of the concave-convex pattern is 4 to less than 30 nm, and
the aspect ratio of a convex portion of the concave-convex pattern is 1 to 10.

13. The method for manufacturing a cured product pattern according to claim 10, further comprising, between the second step and the third step, a step of aligning the substrate with the mold.

14. The method for manufacturing a cured product pattern according to claim 10, wherein the first step to the fourth step are repeatedly performed a plurality of times on different regions on the substrate.

15. (canceled)

16. A method for manufacturing an optical component, the method comprising: a step of obtaining a cured product pattern by the method for manufacturing a cured product pattern according to claim 10.

17. A method for manufacturing a circuit board, the method comprising:
a step of obtaining a cured product pattern by the method for manufacturing a cured product pattern according to claim 10; and
a step of performing etching or ion implantation on the substrate using the cured product pattern as a mask.

18. The method for manufacturing a circuit board according to claim 17, wherein the circuit board is a circuit board used for a semiconductor element.

19. A method for manufacturing a liquid material for nanoimprint, the method comprising:
a purification step of purifying a liquid material for nanoimprint by filtration with a filter, wherein the purification step comprises:
[a] a step of filtrating a crude liquid material for nanoimprint at a flow rate of less than 0.03 L/min with a filter having a pore diameter of 50 nm or less; and
[b] a step of recovering a flow fraction of the crude liquid material for nanoimprint passing through the filter other than an initial flow fraction in a container connected to a particle number concentration measuring system.

20. The liquid material for nanoimprint according to claim 1, wherein the particle contains an air bubble.

21. The liquid material for nanoimprint according to claim 1, wherein concentration of metal impurities is 100 ppb or lower.
